(19) United States
(12) Patent Application Publication
(10) Pub. No.: US 2026/0002282 A1
(43) Pub. Date: Jan. 1, 2026

(54) ELECTRODEPOSITION SYSTEMS

(71) Applicant: Lam Research Corporation, Fremont, CA (US)

(72) Inventors: Zhian HE, Lake Oswego, OR (US); Navaneetha Krishnan SUBBAIYAN, Portland, OR (US); Swapnil Dattatray DESHMUKH, Tualatin, OR (US); Cian SWEENEY, Portland, OR (US); Benjamin SMEDLEY, Beaverton, OR (US); Jonathan REID, Sherwood, OR (US); Shantinath GHONGADI, Tigard, OR (US)

(21) Appl. No.: 18/993,833

(22) PCT Filed: Jul. 20, 2023
(86) PCT No.: PCT/US2023/070555

§ 371 Date: Jan. 13, 2025

Related U.S. Application Data
(60) Provisional application No. 63/370,481, filed on Aug. 4, 2022.
(60) Provisional application No. 63/379,586, filed on Oct. 14, 2022.
(60) Provisional application No. 63/476,303, filed on Dec. 20, 2022.

(51) Int. Cl. C25D 17/00; C25D 17/06; C25D 21/04; C25D 21/10; C25D 21/18; C25D 21/22

(52) U.S. Cl. CPC C25D 17/002; C25D 17/06; C25D 21/04; C25D 21/10; C25D 21/18; C25D 21/22

(57) ABSTRACT

Examples are disclosed that relate to operating an electrodeposition system comprising an inert anode. In one example system, the electrodeposition system includes a substrate holder and a cathode chamber configured to hold a catholyte. An anode chamber configured to hold an anolyte during the electrodeposition process comprises an inert anode. An intermediate chamber is positioned between the cathode chamber and the anode chamber. The intermediate chamber is separated from the cathode chamber by an ion exchange membrane.

### BACKGROUND

Electrodeposition can be used in integrated circuit manufacturing processes to deposit electrically conductive films onto substrates. Electrodeposition involves the electrochemical reduction of dissolved ions of a selected metal to an elemental state on a substrate to form a film of the selected metal. Electrodeposition systems comprise a cathode that is physically coupled to the substrate and electrically coupled to an anode. One or more barriers may separate the cathode and anode into respective plating chambers. Some anodes may be active and provide the metal for electrodeposition. Other anodes may be inert. Inert anodes drive the electrodeposition reaction by oxidizing other species than a metal being deposited, such as water molecules.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

Examples are disclosed that relate to operating an electrodeposition system comprising an inert anode. In one example system, the electrodeposition system includes a substrate holder. The electrodeposition system further comprises a cathode chamber configured to hold a catholyte. The electrodeposition system further comprises an anode chamber configured to hold an anolyte during an electrodeposition process. The anode chamber comprises an inert anode. An intermediate chamber is positioned between the cathode chamber and the anode chamber. The intermediate chamber is separated from the cathode chamber by an ion exchange.

In some such examples, the intermediate chamber is separated from the anode chamber by a proton-impeding structure.

In some such examples, the proton-impeding structure additionally or alternatively comprises a metal redox barrier configured to receive growth of a metal film on an anode side of the metal redox barrier by reduction of metal ions from anolyte contacting the anode side of the metal redox barrier, and provide metal ions to a solution contacting a cathode side of the metal redox barrier by oxidation of the metal redox barrier.

In some such examples, the electrodeposition system additionally or alternatively comprises a mechanical bias element to bias the metal redox barrier toward the intermediate chamber.

In some such examples, the metal redox barrier additionally or alternatively comprises one or more of copper, cobalt, nickel, tin, silver, gold, cadmium, platinum, or iron.

In some such examples, the metal redox barrier is additionally or alternatively configured to be rotatable to allow the anode side and cathode side to alternate orientations toward the intermediate chamber.

In some such examples, the proton-impeding structure additionally or alternatively comprises an anion exchange membrane.

In some such examples, the electrodeposition system additionally or alternatively comprises an intermediate chamber solution circulation system configured to circulate an intermediate chamber solution through the intermediate chamber.

In some such examples, the ion exchange membrane that separates the intermediate chamber and the cathode chamber additionally or alternatively comprises a second anion exchange membrane.

In some such examples, the ion exchange membrane that separates the intermediate chamber and the cathode chamber additionally or alternatively comprises a cation exchange membrane.

In some such examples, the electrodeposition system additionally or alternatively comprises a redox shuttle circulation system configured to provide a redox shuttle species to the anode chamber.

In some such examples, the redox shuttle circulation system additionally or alternatively comprises a redox shuttle species regeneration chamber.

In some such examples, the ion exchange membrane is additionally or alternatively a first cation exchange membrane, and the intermediate chamber is additionally or alternatively separated from the anode chamber by a second cation exchange membrane.

In some such examples, the electrodeposition system additionally or alternatively comprises a copper oxide module fluidly coupled to the intermediate chamber.

Another example provides an electrodeposition system. The electrodeposition system comprises a substrate holder. The electrodeposition system further comprises a cathode chamber configured to hold a catholyte. The electrodeposition system further comprises an anode chamber comprising an inert anode, the anode chamber configured to hold an anolyte. The electrodeposition system further comprises a first ion exchange membrane positioned between the anode chamber and the cathode chamber. A redox shuttle circulation system is configured to provide a redox shuttle species to the anode chamber.

In some such examples, the first ion exchange membrane additionally or alternatively comprises an anion exchange membrane.

In some such examples, the electrodeposition system further comprises an intermediate chamber being positioned between the cathode chamber and the anode chamber. The intermediate chamber is additionally or alternatively separated from the anode chamber by the anion exchange membrane and is additionally or alternatively separated from the cathode chamber by a cation exchange membrane. The intermediate chamber is configured to hold an intermediate chamber solution during an electrodeposition process.

In some such examples, the electrodeposition system additionally or alternatively comprises a source of metal ions fluidly coupled to the intermediate chamber.

In some such examples, the redox shuttle circulation system additionally or alternatively comprises a redox shuttle species regeneration chamber.

Another example provides an electrodeposition system. The electrodeposition system comprises a substrate holder. The electrodeposition system further comprises a cathode chamber configured to hold a catholyte. The electrodeposition system further comprises an anode chamber comprising an inert anode, the anode chamber configured to hold an anolyte. The electrodeposition system further comprises an anion exchange membrane separating the cathode chamber from the anode chamber.

Another example provides an electrodeposition system. The electrodeposition system comprises a substrate holder. The electrodeposition system further comprises a cathode chamber configured to hold a catholyte. The electrodeposition system further comprises an anode chamber comprising an inert anode. The anode chamber is configured to hold an anolyte. The anode chamber is separated from the cathode chamber by a cation exchange membrane. The electrodeposition system further comprises a copper oxide module fluidly coupled to the anode chamber.

Another example provides an electrodeposition system. The electrodeposition system comprises a cathode chamber configured to hold a catholyte. The electrodeposition system further comprises a substrate holder configured to expose a substrate to the catholyte during an electrodeposition process. The electrodeposition system further comprises an inert anode assembly. The inert anode assembly comprises one or more inert anodes and two or more anolyte flow channels. The two or more anolyte flow channels define segmented areas of anolyte flow across the one or more inert anodes. The inert anode assembly further comprises an ion exchange membrane positioned between the cathode chamber and the two or more anolyte flow channels.

In some such examples, the inert anode assembly alternatively or additionally comprises a cathode chamber bottom component. The cathode chamber bottom component comprises an opening that is positioned opposite an anolyte flow channel of the two or more anolyte flow channels.

In some such examples, the two or more anolyte flow channels are alternatively or additionally formed in an anolyte channel component. The ion exchange membrane is alternatively or additionally positioned between the cathode chamber bottom component and the anolyte channel component.

In some such examples, the inert anode assembly alternatively or additionally comprises an intermediate channel component positioned between the cathode chamber bottom component and the anolyte channel component. Alternatively or additionally the ion exchange membrane is a first ion exchange membrane positioned between the intermediate channel component and the anolyte channel component. The electrodeposition system alternatively or additionally comprises a second ion exchange membrane positioned between the cathode chamber bottom component and the intermediate channel component.

In some such examples, alternatively or additionally the intermediate channel component at least partially defines an intermediate flow channel. The intermediate flow channel comprises an opening that is positioned opposite an anolyte flow channel of the two or more anolyte flow channels.

In some such examples, the two or more anolyte flow channels alternatively or additionally are configured to generate a linear flow velocity in a range of 0.1 to 10 meters per second.

In some such examples, the one or more inert anodes alternatively or additionally comprise a first inert anode associated with a first anolyte flow channel and a second inert anode associated with a second anolyte flow channel.

In some such examples, the one or more inert anodes alternatively or additionally comprise a shared inert anode that is shared between at least two of the two or more anolyte flow channels.

Another example provides an inert anode assembly. The inert anode assembly comprises one or more inert anodes and two or more anolyte flow channels. The two or more anolyte flow channels define segmented areas of anolyte flow across the one or more inert anodes.

In some such examples, the inert anode assembly alternatively or additionally comprises a cathode chamber bottom component. The cathode chamber bottom component comprises an opening that is positioned opposite an anolyte flow channel of the two or more anolyte flow channels.

In some such examples, the two or more anolyte flow channels alternatively or additionally are formed in an anolyte channel component. The inert anode assembly alternately or additionally comprises an ion exchange membrane positioned between the cathode chamber bottom component and the anolyte channel component.

In some such examples, the inert anode assembly alternatively or additionally comprises an intermediate channel component positioned between the cathode chamber bottom component and the anolyte channel component. The ion exchange membrane is alternatively or additionally a first ion exchange membrane positioned between the intermediate channel component and the anolyte channel component. The inert anode assembly alternatively or additionally comprises a second ion exchange membrane positioned between the cathode chamber bottom component and the intermediate channel component.

In some such examples, alternatively or additionally the intermediate channel component at least partially defines an intermediate flow channel. The intermediate flow channel comprises an opening that is positioned opposite an anolyte flow channel of the two or more anolyte flow channels.

In some such examples, the one or more inert anodes alternatively or additionally comprise a first inert anode associated with a first anolyte flow channel and a second inert anode associated with a second anolyte flow channel.

In some such examples, the one or more inert anodes alternatively or additionally comprise a shared inert anode that is shared between at least two of the two or more anolyte flow channels.

Another example provides a method for operating an electrodeposition system. The electrodeposition system comprises an inert anode assembly. The method comprises placing a substrate in a cathode chamber of the electrodeposition system. The method further comprises exposing the substrate to a catholyte in the cathode chamber. The method further comprises, during an electrodeposition process, generating cations and gas bubbles in an anolyte at an inert anode of the inert anode assembly. The method further comprises flowing the anolyte within an anolyte flow channel at a sufficient linear flow velocity to prevent gas bubbles from accumulating on an ion exchange membrane between the anolyte flow channel and the catholyte.

In some such examples, flowing the anolyte at the sufficient linear flow velocity alternatively or additionally comprises flowing the anolyte with a linear flow velocity in a range of 0.1 to 10 meters per second.

In some such examples, flowing the anolyte at the sufficient linear flow velocity alternatively or additionally comprises restricting anolyte flow to segmented areas by using two or more anolyte flow channels formed in an anolyte channel component of the inert anode assembly, the two or more anolyte flow channels comprising the anolyte flow channel.

In some such examples, generating the cations and the gas bubbles in the anolyte at the inert anode alternatively or additionally comprises generating the cations and the gas bubbles in an anolyte of a first anolyte flow channel at a first inert anode and in an anolyte of a second anolyte flow channel at a second inert anode.

In some such examples, generating the cations and the gas bubbles in the anolyte at the inert anode alternately or additionally comprises generating the cations and the gas bubbles within a first anolyte flow channel and within a second anolyte flow channel using a shared inert anode.

Another example provides an inert anode assembly. The inert anode assembly comprises an inert anode and an anolyte flow channel. The anolyte flow channel defines an area of anolyte flow across the inert anode. The anolyte flow channel comprises a length and a width. The width is smaller than the length. The anolyte flow channel comprises a directional change along the length.

In some such examples, the anolyte flow channel alternately or additionally comprises a spiral path.

In some such examples, the anolyte flow channel alternately or additionally comprises a serpentine path.

Another example provides an electrodeposition system comprising a cathode chamber configured to hold a catholyte, an anode chamber configured to hold an anolyte, and a membrane frame supporting an ion exchange membrane positioned between the cathode chamber and the anode chamber. The electrodeposition system further comprises a substrate holder configured to expose a substrate to the catholyte during an electrodeposition process. An inert anode is positioned within the anode chamber. A bubble diverter is positioned to direct a flow of bubbles generated at the inert anode to a stilling structure at which the bubbles are vented to atmosphere.

In some such examples, the bubble diverter additionally or alternatively extends around a peripheral portion of the ion exchange membrane.

In some such examples, the bubble diverter additionally or alternatively comprises a plurality of apertures configured to expose the ion exchange membrane to ionic current flowing between the inert anodes and the substrate.

In some such examples, the electrodeposition system additionally or alternatively comprises an adjustment mechanism configured to adjust an open cross-sectional area of the plurality of apertures.

In some such examples, the plurality of apertures are additionally or alternatively located at a lower end of the bubble diverter, and the adjustment mechanism additionally or alternatively comprises a mechanism for adjusting a position of the bubble diverter relative to a base of the anode chamber.

In some such examples, the electrodeposition additionally or alternatively comprises an anolyte circulation loop, and the bubble diverter additionally or alternatively directs the flow of bubbles to the anolyte circulation loop.

In some such examples, the anolyte circulation loop additionally or alternatively comprises a circulation pump, and the stilling structure is additionally or alternatively positioned upstream of the circulation pump, the stilling structure exposed to atmosphere.

In some such examples, the anolyte circulation loop additionally or alternatively comprises a contactor downstream of the stilling structure and upstream of the circulation pump, the contactor configured to remove dissolved gases from the anolyte.

Another example provides a bubble diversion system for an electrodeposition system. The bubble diversion system comprises a bubble diverter configured to be mounted in an anode chamber of an electrodeposition system, the bubble diverter comprising a wall configured to partially separate a region of the anode chamber adjacent to an ion exchange membrane from a region of the anode chamber configured to direct a flow of bubbles to an anolyte circulation loop.

In some such examples, the bubble diverter is additionally or alternatively configured to extend around a peripheral portion of the ion exchange membrane.

In some such examples, the bubble diverter additionally or alternatively comprises a plurality of apertures configured to expose the ion exchange membrane to ionic current flowing between an inert anode and a substrate.

In some such examples, the bubble diversion system additionally or alternatively comprises an adjustment mechanism configured to adjust an open cross-sectional area of the plurality of apertures.

In some such examples, the adjustment mechanism additionally or alternatively comprises a shutter system.

In some such examples, the bubble diversion system additionally or alternatively comprises a stilling port configured to direct bubbles out of the anode chamber to a stilling structure.

In some such examples, the stilling port additionally or alternatively leads to channels configured to connect to an anolyte circulation loop.

Another example provides a method of operating an electrodeposition system. The method comprises generating bubbles at an inert anode positioned within an anode chamber of the electrodeposition system. The method further comprises directing the bubbles generated at the inert anode to a stilling structure by using a bubble diverter, the stilling structure being exposed to atmosphere.

In some such examples, directing bubbles to the stilling structure additionally or alternatively comprises biasing a flow of the bubbles to at least one channel leading to an anolyte circulation loop.

In some such examples, the method additionally or alternatively comprises flowing anolyte through the anolyte circulation loop such that the bubbles enter the stilling structure upstream of a circulation pump.

In some such examples, the method additionally or alternatively comprises generating an ionic current at the inert anode, flowing the ionic current through apertures of the bubble diverter, and responsive to an indication of plating performance, adjusting the ionic current at a substrate by adjusting an open cross-sectional area of at least one aperture of the bubble diverter.

In some such examples, adjusting the ionic current additionally or alternatively comprises maintaining a voltage applied between the inert anode and a substrate.

### BRIEF DESCRIPTION OF THE DRAWINGS

FIG. 1 shows a block diagram of an example electrodeposition tool.

FIG. 2 schematically shows an example electrodeposition cell comprising an inert anode.

FIG. 3 schematically illustrates an example electrodeposition system comprising an inert anode and a proton-impeding structure.

FIG. 4 schematically illustrates an example electrodeposition system comprising a metal redox barrier.

FIG. 5 schematically illustrates an example electrodeposition system comprising a rotatable metal redox barrier.

FIG. 6A schematically illustrates an example electrodeposition system comprising an inert anode, a cation exchange membrane, and an anion exchange membrane.

FIG. 6B shows plots illustrating changes in bath ion concentrations over time for an example embodiment of the electrodeposition system of FIG. 6A.

FIG. 7 schematically illustrates an example electrodeposition system comprising an inert anode redox shuttle circulation system.

FIG. 8 schematically illustrates an example chemistry for the electrodeposition system of FIG. 7.

FIG. 9A schematically illustrates an example electrodeposition system comprising an inert anode, a first anion exchange membrane, and a second anion exchange membrane.

FIG. 9B shows plots illustrating changes in bath ion concentrations over time for an example embodiment of the electrodeposition system of FIG. 9A.

FIG. 10 schematically illustrates an example electrodeposition system comprising an inert anode, a first cation exchange membrane, a second cation exchange membrane, and a copper oxide module.

FIG. 11A schematically illustrates an example electrodeposition system comprising an inert anode and an anion exchange membrane.

FIG. 11B shows plots illustrating changes in bath concentrations over time for an example embodiment of the electrodeposition system of FIG. 11A.

FIG. 12 shows a flow diagram depicting an example method for forming a layer of a selected metal material on a substrate by electrodeposition.

FIG. 13 shows a block diagram of another example electrodeposition system.

FIG. 14 schematically shows a top view of an example inert anode assembly.

FIG. 15 schematically shows an exploded view of the inert anode assembly of FIG. 14.

FIG. 16 schematically shows a sectional side view taken along line 5-5 of FIG. 14.

FIG. 17 schematically shows an example inert anode assembly having a shared inert anode.

FIG. 18 schematically shows an example inert anode assembly having an anolyte flow channel with a spiral path.

FIG. 19 schematically shows an example inert anode assembly having an anolyte flow channel with a serpentine path.

FIG. 20 schematically shows an example inert anode assembly having an intermediate channel component.

FIG. 21 shows a flow diagram of an example method for operating an electrodeposition system comprising an inert anode.

FIG. 22 shows a block diagram of another example electrodeposition system.

FIG. 23 shows a diagram of ionic current and oxygen bubble movement in an example electrodeposition system.

FIG. 24 schematically shows an anolyte circulation loop comprising a stilling area.

FIG. 25 schematically shows a top view of an electrodeposition system comprising peripheral inert anodes and a bubble diverter.

FIGS. 26A-26B show an example bubble diverter comprising shuttered apertures.

FIGS. 27A-27B show repositioning of an example bubble diverter relative to a base of an anode chamber.

FIG. 28 shows a flow diagram of an example method for operating an electrodeposition system comprising an inert anode.

FIG. 29 shows a flow diagram of an example method for adjusting ionic current in an electrodeposition system comprising an inert anode.

FIG. 30 schematically shows an example computing system.

### DETAILED DESCRIPTION

The term “acidic species” generally represents an atom or molecule, in neutral or ionic form, capable of donating a proton or receiving an electron pair.

The term “active anode” generally represents an electrode in an electrodeposition system that is formed of a metal being electrodeposited and that is consumed by oxidation during an electrodeposition process.

The term “anion exchange membrane” generally represents a membrane that selectively passes one or more anionic species while blocking the transport of other species, such as cationic species and organic species.

The term “anode” generally represents an electrically conductive structure at which electrochemical oxidation occurs during an electrodeposition process.

The term “anode chamber” generally represents a physical structure configured to hold at least an anode and anolyte in an electrodeposition system.

The term “anode chamber base” generally represents a lower surface of an anode chamber.

The term “anode side” generally represents a side of an electrodeposition system component that faces toward an inert anode of an electrodeposition system.

The term “anolyte” generally represents a solution used in an anode chamber during an electrodeposition process.

The term “anolyte circulation loop” generally represents a path along which anolyte is recirculated though an anode chamber over time.

The term “anolyte flow channel” generally represents a structure that defines a fluid flow path of anolyte across an inert anode. The fluid flow path comprises a width and a length, where the width is smaller than the length.

The term “anolyte channel component” generally represents a structure that defines at least a portion of an anolyte flow channel.

The term “aperture” generally represents a hole or opening in a partition that allows for trafficking of molecules from one side of the partition to another side of the partition.

The term “bubble diverter” generally represents a structure that biases the flow of bubbles in a solution to a pre-selected location.

The term “bubble diversion system” generally represents a system comprising a bubble diverter and at least a conduit to remove bubbles from a chamber holding a solution.

The term “cathode” generally represents a conductive layer on a substrate that is grown during electrodeposition by the electrochemical reduction of ions.

The term “cathode chamber” generally represents a physical structure configured to hold at least a cathode and catholyte in an electrodeposition system.

The term “cathode chamber bottom component” generally represents a structure that defines a surface of a cathode chamber located adjacent to an ion exchange membrane that separates the cathode chamber from another fluid environment of an electrodeposition system. Examples of other fluid environments include intermediate flow channels and anolyte flow channels.

The term “cathode side” generally represents a side of an electrodeposition system component that faces toward a substrate holder of the electrodeposition system.

The term “catholyte” generally represents a solution used in a cathode chamber during an electrodeposition process.

The term “cation exchange membrane” generally represents a permeable membrane that selectively passes one or more cationic species while blocking the transport of other species, such as anionic species and organic species.

The term “circulation pump” generally represents a pump that recirculates liquids and/or gases through a circulation loop.

The term “contactor” generally represents a device comprising a membrane configured to remove dissolved gases from a solution.

The term “dissolved gases” generally refers to gas molecules that have been dissolved in a solvent.

The terms “electrodeposition,” “electroplating,” “plating,” “deposition” and variants thereof generally represents a process in which dissolved ions of one or more metals are reduced on a substrate surface to form a film of the one or more metals.

The term “electrodeposition cell” generally represents a processing station in an electrodeposition system for performing electrodeposition on substrates.

The term “electrodeposition system” generally represents a machine configured to perform electrodeposition.

The term “gas bubbles” generally represents bubbles of a gas phase byproduct produced at an inert anode during an electrodeposition process.

The term “inert anode” generally represents an electrode material that is conductive, but that is not electrochemically oxidized during an electrodeposition process.

The term “inert anode assembly” generally represents an assembly of components that include an inert anode and an anolyte channel component.

The term “intermediate chamber” generally represents a physical structure positioned between a cathode chamber and an anode chamber that provides selective separation from chemical environments in the cathode chamber and the anode chamber.

The term “intermediate chamber solution” generally represents a solution used in an intermediate chamber during an electrodeposition process.

The term “intermediate chamber solution circulation system” generally represents a path along which an intermediate chamber solution is recirculated over time.

The term “intermediate channel component” generally represents a structure that defines at least a portion of an intermediate flow channel.

The term “intermediate flow channel” generally represents a structure that defines a fluid flow path of an intermediate electrolyte. An intermediate flow channel is separated from an anolyte flow channel by a first ion exchange membrane, and from a catholyte by a second ion exchange membrane.

The term “ionic current” generally represents a flow of electrical charge through a conductive solution.

The term “ion exchange membrane” generally represents a semi-permeable membrane that allows the transport of certain dissolved ions, but not other dissolved ions or neutrally charged molecules.

The term “linear flow velocity” generally represents a distance traveled by an anolyte over a unit of time.

The term “lower end of the bubble diverter” generally represents portions of the bubble diverter proximate to an anode chamber base.

The term “mechanical bias element” generally represents a device configured to apply mechanical force along a direction.

The term “membrane frame” generally represents a structural device to which a membrane can be attached and fixed in place.

The term “membrane interface seal” generally represents a material positioned between a membrane and an adjacent structure that prevents flow of solution between the membrane and the adjacent structure.

The term “metal film” generally represents a layer of metal deposited onto a substrate.

The term “metal ion” generally represents a metal atom in a soluble oxidation state.

The term “metal redox barrier” generally represents a physical barrier that blocks proton and bubble migration while permitting flow of electrical current. Electrical current flows by oxidation of the metal redox barrier on a cathode-facing surface of the metal redox barrier and reductive deposition of metal atoms onto an anode-facing surface of surface of the metal redox barrier.

The term “open cross-sectional area” generally represents the two-dimensional extent of an aperture.

The term “proton impeding structure” generally represents any barrier that impedes migration of protons out of an anode chamber within an electrodeposition cell.

The term “redox shuttle circulation system” generally represents a circulating bath loop configured to provide to an inert anode a flow of a chemical species that is oxidized preferentially over water.

The term “redox shuttle species regeneration chamber” generally represents a portion of a redox shuttle circulation system that regenerates the chemical species that is oxidized by an inert anode preferentially over water.

The term “segmented areas of anolyte flow” and variants thereof generally represent flows of anolyte across one or more inert anodes that are spatially separated by a solid physical structure.

The term “shared inert anode” generally represents a contiguous inert anode that is configured to contact anolyte within two or more anolyte flow channels.

The term “shutter system” generally represents a device that is moveable to increase or decrease the open cross-sectional area of an aperture.

The term “stilling port” generally represents an opening in a chamber that leads to a stilling area that is exposed to atmosphere.

The term “stilling structure” generally represents a device in which gas bubbles in a solution are vented to atmosphere.

The term “substrate” generally represents any object on which a film can be deposited by electrodeposition.

The term “substrate holder” generally represents a device configured to receive a substrate and to hold the substrate in a position for metal film electrodeposition.

Electrochemical deposition processes are widely used in the semiconductor industry for device metallization. Example metallization processes include electrodeposition of copper and cobalt onto chips and other substrates. Other metals commonly used in electrodeposition processes include tin/silver alloys, nickel, and gold.

Some electrodeposition systems use consumable or active anodes. An active anode generally comprises the same metal being deposited at the cathode. Active anodes are consumed over time. The consumption of active anodes necessitates periodic replacement, recalibration, and corresponding tool downtime. Further, active anodes may be expensive and difficult to source for some metals. To avoid such problems, an electrodeposition system can utilize an inert anode. Inert anodes are not consumed over time. However, inert anodes drive electrolysis reactions in the anode chamber that produce protons and oxygen bubbles. The protons and oxygen bubbles may interfere with electrodeposition. For example, the oxygen bubbles may accumulate beneath an ion exchange membrane that separates an anode chamber and a cathode chamber of the electrodeposition system. The accumulated bubbles can occlude a target substrate, block ionic current through the ion exchange membrane, and result in non-uniform electrodeposition. Further, without the anode as a source of plating ions, more active catholyte bath management may need to be used to prevent plating ion depletion.

Thus, example electrodeposition systems are disclosed that may address issues related to proton and oxygen bubble generation by inert anodes. Briefly, in some examples, a proton-impeding structure separates the anode chamber from an intermediate chamber. Further, an ion-exchange membrane separates the intermediate chamber from the cathode chamber. In some such examples, the proton-impeding structure comprises a metal redox barrier. In other such examples, the proton-impeding structure comprises a second ion-exchange membrane. Further, some such examples comprise a redox shuttle circulation system to help further reduce acid production at the inert anode. The redox shuttle circulation system may include a regeneration chamber to help maintain chemical species concentrations in the anolyte.

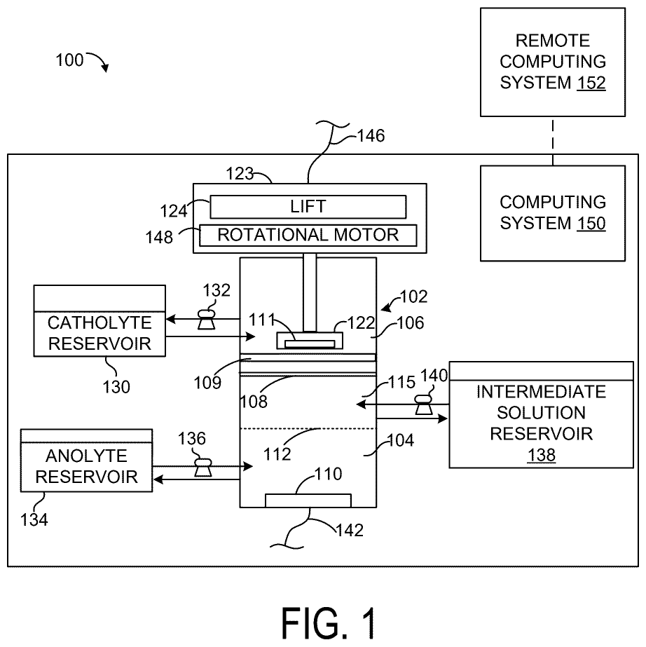

Prior to discussing these examples in more detail, FIG. 1 schematically shows a block diagram of an example electrodeposition tool 100. Electrodeposition tool 100 comprises an electrodeposition cell 102 comprising an anode chamber 104 and a cathode chamber 106. Electrodeposition tool 100 further comprises an ion exchange membrane 108 separating the anode chamber 104 and the cathode chamber 106. In various examples, ion exchange membrane 108 may comprise a cation exchange membrane or an anion exchange membrane. Electrodeposition tool 100 further comprises a high resistance virtual anode (HRVA) 109 within cathode chamber 106.

Anode chamber 104 comprises an anode 110. Anode chamber 104 further comprises an anolyte. Cathode chamber 106 comprises a catholyte. The catholyte comprises an ionic species to be deposited on a cathode layer of a substrate 111 as a metal by electrochemical reduction. Anode 110 may comprise an inert anode. Bulk anolyte and/or catholyte solutions may be added at times to replenish the ionic species.

Ion exchange membrane 108 inhibits organic species and anionic species from crossing between cathode chamber 106 and anode chamber 104, while allowing metal ions to cross from anode chamber 104 to cathode chamber 106. HRVA 109 comprises an ionically resistive element that approximates a suitably constant and uniform current source in proximity to a substrate cathode.

Electrodeposition tool 100 further comprises a proton impeding structure 112 positioned between anode 110 and ion exchange membrane 108 to reduce the acidification of the catholyte. Proton impeding structure 112 forms a boundary of an intermediate chamber 115 situated between anode chamber 104 and cathode chamber 106. Another boundary of intermediate chamber 115 may be formed by ion exchange membrane 108. Intermediate chamber 115 may comprise an intermediate solution. The intermediate solution may include the ionic species to be deposited on a cathode layer.

Substrate holder 122 is coupled to a substrate holder movement system 123. Substrate holder movement system 123 comprises a lift 124 configured to adjust a spacing between substrate holder 122 and HRVA 109. For example, lift 124 may lower substrate holder 122 to position substrate 111 within the catholyte for electrodeposition. Lift 124 further may raise substrate holder 122 from the catholyte after electrodeposition. Substrate holder movement system 123 further may comprise components to control the opening and closing of substrate holder 122.

The catholyte may be circulated between cathode chamber 106 and a catholyte reservoir 130 via a combination of gravity and one or more pumps 132. Likewise, the anolyte may be circulated through anolyte reservoir 134 and anode chamber 104 via a combination of gravity and one or more pumps 136. Further, intermediate solution may be circulated through intermediate solution reservoir 138 via a combination of gravity and one or more pumps 140.

In some electrodeposition tools, plating operations may be performed in parallel on multiple substrates using multiple plating cells. In some such examples, central catholyte and/or anolyte reservoirs may supply multiple plating cells with catholyte and/or anolyte. In other such examples, separate catholyte and/or anolyte reservoirs may be used to supply multiple plating cells. In yet other examples, an electrodeposition tool may comprise a single plating cell. Where an electrodeposition tool comprises multiple plating cells, a single lift may be configured to lift two or more substrate holders for two or more different plating cells.

Substrate holder 122 is lowered by lift 124 toward HRVA 109 after substrate 111 is loaded into substrate holder 122. Substrate 111 faces a surface of the HRVA 109, and is spaced from HRVA 109 by a plating gap during electrodeposition. An electric field is established between anode 110 and substrate 111. This electric field drives dissolved metal cations from anode chamber 104 and/or intermediate chamber 115 into cathode chamber 106. At the substrate 111, the metal cations are electrochemically reduced to deposit a metal film on substrate 111. An anodic potential is applied to anode 110 via an anode electrical connection 142 and a cathodic potential is provided to the cathode of substrate 111 via a cathode electrical connection 146 to form a circuit. In some examples, substrate holder 122 may be rotated via a rotational motor 148 during electrodeposition.

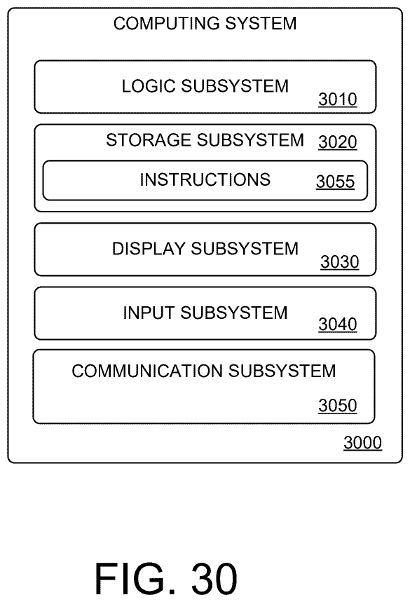

Electrodeposition tool 100 further comprises a computing system 150, aspects of which are described in more detail below with regard to FIG. 30. Computing system 150 may comprise instructions executable to control any suitable functions of electrodeposition tool 100. Example functions include electrodeposition processes and substrate loading/unloading processes. In some examples, computing system 150 may be configured to communicate with a remote computing system 152 via a suitable computer network. Remote computing system 152 may comprise any suitable computing system. Examples include a networked workstation computer, an enterprise computing system, and/or a cloud computing system. It will be understood that remote computing system 152 may be in communication with and control a plurality of electrodeposition tools in some examples.

Active anodes may find more frequent use than inert anodes. However, as mentioned above, a drawback of using an active anode is that active anodes are eventually consumed over time. New anodes thus are installed periodically. Active anodes may be expensive and difficult to source for some metals. Also, anode replacement leads to electrodeposition system downtime. Anode replacement further may involve re-qualification and defect control of the electrodeposition system following the anode installation. The loss of productivity from anode replacement may decrease throughput and increase the cost of ownership of an electrodeposition system.

In contrast, as mentioned above, inert anodes are not consumed over time. Thus, the use of inert anode does not lead to downtime due to anode replacement. These features may make inert anodes an attractive alternative to active anodes.

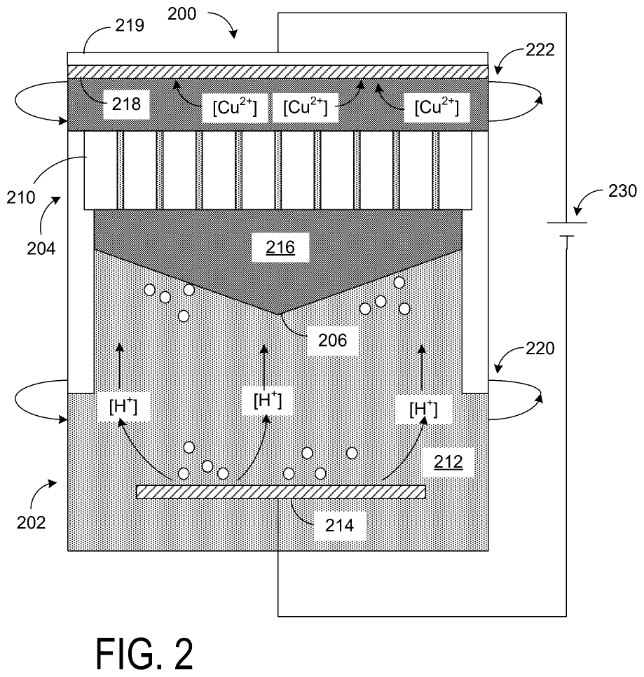

However, as mentioned above, inert anodes may produce protons and oxygen bubbles. FIG. 2 schematically shows an example electrodeposition system 200 comprising an inert anode and illustrates proton and oxygen bubble formation. FIG. 2 is described in the context of copper deposition. However, bubbles also may be generated when electrodepositing other metals.

Electrodeposition system 200 comprises an anode chamber 202 and a cathode chamber 204. Electrodeposition system 200 further comprises an ion exchange membrane 206 separating anode chamber 202 and cathode chamber 204. Electrodeposition system 200 further comprises a HRVA 210 disposed within cathode chamber 204.

Anode chamber 202 comprises an anolyte bath 212 in which inert anode 214 is disposed. Cathode chamber 204 comprises a catholyte bath 216 that comprises ionic copper (Cu²⁺) to be deposited onto a substrate 218 that acts as a cathode. Substrate 218 is held within a substrate holder 219 during deposition. Anolyte bath 212 is located within an anolyte circulating loop 220. Catholyte bath 216 is located within a catholyte circulating loop 222. A voltage source 230 applies a voltage across substrate 218 and inert anode 214 to drive flow of copper ions for deposition on substrate 218.

Cation exchange membrane 206 passes Cu²⁺ions from anolyte bath 212 to catholyte bath 216. The Cu²⁺ions crossing cation exchange membrane 206 replace at least some copper ions in catholyte bath 216 that are reduced onto substrate 218.

For the inert anode of FIG. 2, the oxidation and reduction reactions comprise:

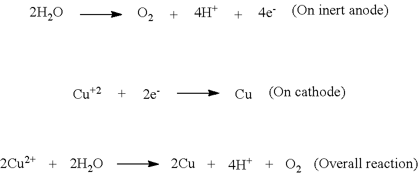

As such, unlike an active anode, inert anode 214 does not produce metal cations in the anolyte bath. Instead, inert anode 214 oxidizes water molecules to form molecular oxygen. For 1 mole of copper plated at the cathode, 0.5 mole of molecular oxygen and 2 moles of protons (H⁺) are generated at the inert anode.

Bubble generation and bubble accumulation at cation exchange membrane 206 may impact plating uniformity. Further, protons generated on the anode surface reduces the pH of the anolyte bath. Protons also may also cross over the membrane into the catholyte bath. Also, it may be challenging to maintain the mass balance, e.g., of copper, in the anode chamber bath during an electrodeposition process.

Challenges with maintaining mass balance in the presence of an inert anode also include concentration swings in the anolyte and catholyte solutions. Concentration swings may be driven by at least three factors: (1) acid generation on the anode surface; (2) acid crossing over the cation exchange membrane to the catholyte side, requiring dosing/bleeding of water to maintain plating specifications; and (3) metal ions being consumed on the cathode surface.

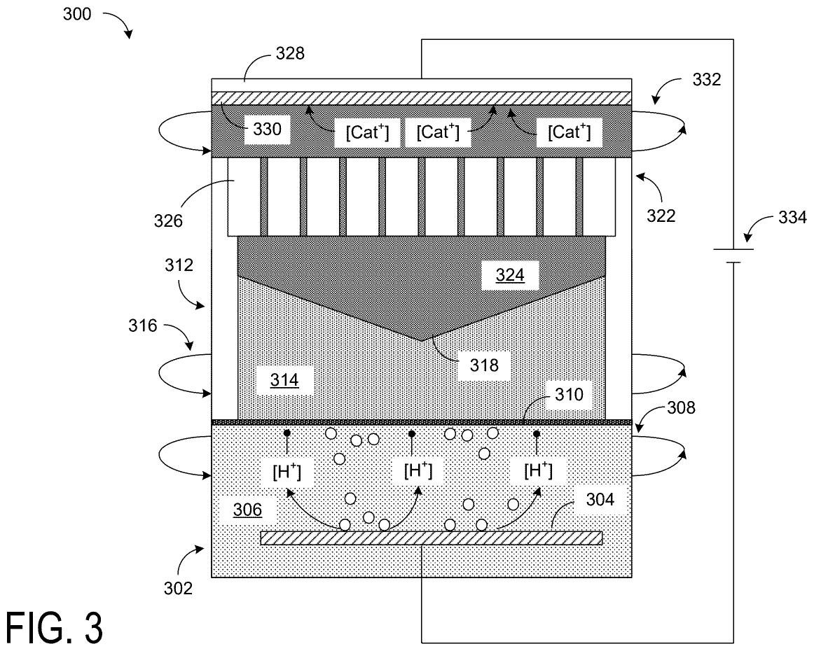

FIG. 3 schematically illustrates an example electrodeposition system 300 that may help to address issues caused by proton and oxygen bubble generation. Electrodeposition system 300 comprises an inert anode 304 disposed in an anode chamber 302. Anode chamber 302 is configured to hold an anolyte bath 306 during the electrodeposition process. Anolyte bath 306 may be replenished via anolyte circulation loop 308. Inert anode 304 may comprise any suitable material that is resistant to oxidation in an electrodeposition process. Examples include mixed metal oxides, or a noble conductive metal such as platinum or iridium coated by one or more metal oxides.

Electrodeposition system 300 further comprises a proton-impeding structure 310. Proton-impeding structure 310 is configured to impede migration of protons and oxygen bubbles resulting from electrolysis of water within anolyte bath 306. This may help to avoid protons migrating to catholyte bath 324. This further may help to avoid oxygen bubble buildup on ion exchange membrane 318. In various examples, proton-impeding structure 310 may comprise one or more of a metal redox barrier, an anion exchange membrane, or other structural element that provides a barrier to proton migration.

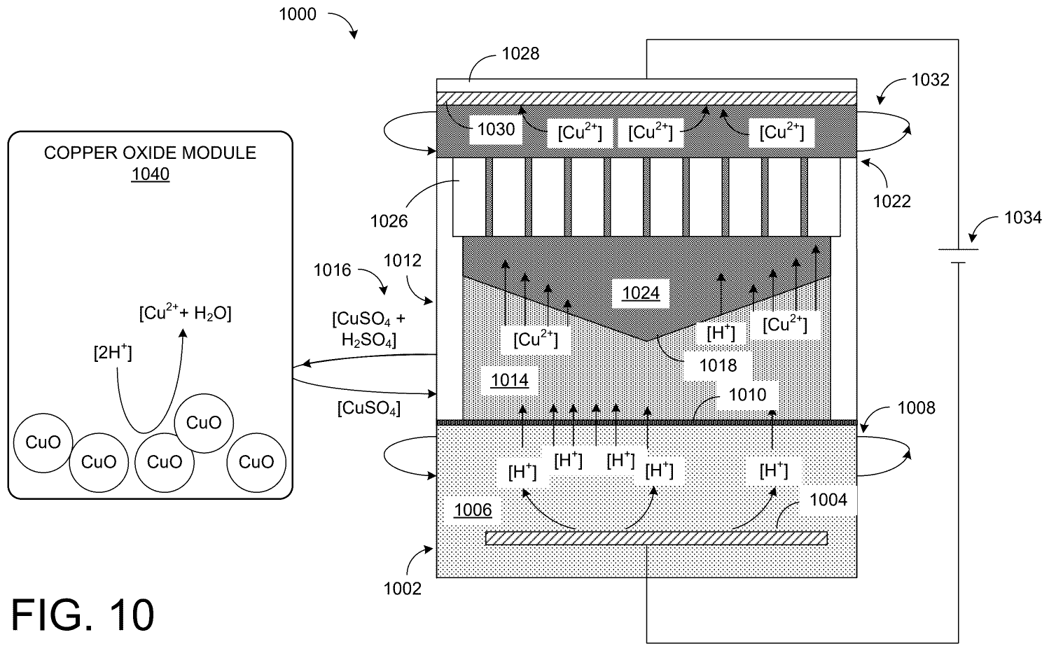

Proton-impeding structure 310 may define a boundary of an intermediate chamber 312. Intermediate chamber 312 may be configured to hold an intermediate bath 314. Intermediate bath 314 may be replenished via intermediate bath circulating loop 316. Intermediate bath 314 may comprise at least a source of metal cations for electrodeposition. In other examples, such as the example described with regard to FIG. 10, the boundary between intermediate chamber 312 and anode chamber 302 may be defined by a structure that does not provide a barrier to proton migration, such as an anion exchange membrane. Such a structure may impede bubble buildup, restrict, or impede the trafficking of one or more molecule types between intermediate chamber 312 and anode chamber 302, and/or otherwise provide a demarcation between the two adjacent chambers.

Electrodeposition system 300 further comprises an ion exchange membrane 318. Ion exchange membrane 318 may define another boundary of intermediate chamber 312. Ion exchange membrane 318 separates intermediate chamber 312 from cathode chamber 322. Ion exchange membrane 318 allows selective transport of ions between intermediate bath 314 and catholyte bath 324.

Cathode chamber 322 further includes HRVA 326 and a substrate holder 328. Substrate holder 328 may be configured to expose a cathode layer of a substrate 330 positioned in substrate holder 328 to catholyte bath 324 during an electrodeposition process. Cations for electrodeposition are indicated in FIG. 3 as Cat⁺. Cat⁺ may represents any suitable metal ion used to grow a metal film in an electrodeposition process. Catholyte bath 324 may be replenished via catholyte circulating loop 332. Voltage source 334 may apply a voltage across inert anode 304 and substrate 330 to drive the electrodeposition process.

As mentioned above, proton-impeding structure 310 may comprise a metal redox barrier in some examples. A metal redox barrier may comprise a physical barrier that blocks proton and bubble migration while permitting flow of electrical current. Electrical current flows by oxidation of the metal redox barrier on a cathode-facing surface of the metal redox barrier and reductive deposition of metal atoms onto an anode-facing surface of surface of the metal redox barrier.

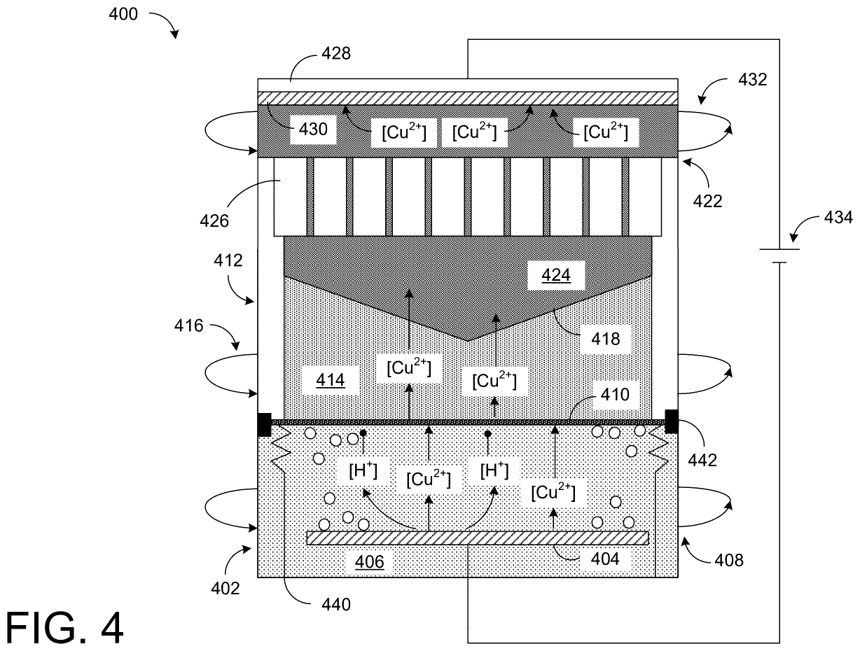

FIG. 4 depicts an example electrodeposition system 400 comprising a metal redox barrier 410. Electrodeposition system 400 is an example of electrodeposition system 300. Briefly, electrodeposition system 400 includes an anode chamber 402 comprising an inert anode 404. Anode chamber 402 is configured to hold an anolyte bath 406 that may be replenished via anolyte circulation loop 408.

Metal redox barrier 410 separates an intermediate chamber 412 from anode chamber 402. Intermediate chamber 412 may be configured to hold an intermediate bath 414. Intermediate bath 414 may be replenished via intermediate bath circulating loop 416. A cation exchange membrane 418 separates intermediate chamber 412 from cathode chamber 422.

In some examples, a same anolyte solution, such as a copper sulfate solution, may be used as both intermediate bath 414 and anolyte bath 406. In other examples, different solutions may be used for intermediate bath 414 and anolyte bath 406. Intermediate bath 414 and anolyte bath 406 respectively may be continuously replenished via anolyte circulating loop 408 and intermediate bath circulating loop 416. Due to proton formation during electrodeposition, anolyte bath 406 may be more acidic than intermediate bath 414. However, the intermediate bath 414 and anolyte bath 406 may be supplied from a same original source and one or both baths doped or diluted prior to entering the respective chamber.

Cathode chamber 422 further includes HRVA 426 and a substrate holder 428. A substrate 430 comprising a cathode layer may be positioned in substrate holder 428 and exposed to catholyte bath 424 during an electrodeposition process. Catholyte bath 424 may be replenished via catholyte circulating loop 432. Voltage source 434 may apply a voltage across inert anode 404 and substrate 430 to drive the electrodeposition process.

Metal redox barrier 410 may comprise a passive metal plate positioned within the electrical field created by voltage source 434 across the cathode layer of substrate 430 and inert anode 404. This may allow for convenient retrofitting of existing electrodeposition system configurations. Metal redox barrier 410 may comprise any suitable metal. Examples include one or more of copper, cobalt, gold, silver, tin, zinc, nickel, cadmium, platinum, iron, or alloys such as brass or tin-silver. In some examples, metal redox barrier 410 may comprise a metal layer on a substrate. The metal layer participates in oxidation and reduction reactions. In other examples, metal redox barrier 410 may comprise a bulk portion formed from the metal that participates in oxidation and reduction reactions. While described in terms of a passive metal plate, in other examples an electric potential may be applied to metal redox barrier 410.

During electrodeposition, metal redox barrier 410 may receive growth of a metal film on an anode side of metal redox barrier 410 by reduction of metal ions from anolyte bath 406. Further, metal redox barrier 410 may provide metal ions to intermediate bath 414 on the cathode side of metal redox barrier 410 by oxidation of metal redox barrier 410.

As an example, copper metal is deposited (reduced) on the anode side of metal redox barrier 410, and copper ions are released (oxidized) on the cathode side of metal redox barrier 410. The resulting copper ions then traverse cation exchange membrane 418, enter catholyte bath 424, and are reduced on substrate 430. As such, an amount of copper that is present in catholyte bath 424 is maintained due to release of copper ions from metal redox barrier 410.

For copper, the primary reactions are as follows:

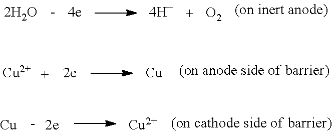

In the absence of mass transport limitations, a Gibbs free energy will generally be favorable to such reactions at the metal redox barrier during plating. This copper replenishment allows the catholyte mass balance to be preserved. In this way, metal redox barrier 410 acts similarly to an active anode. Metal redox barrier 410 also helps to maintain a desired acid concentration in the intermediate bath 414 by blocking proton migration into intermediate bath 414.

As copper deposits on the anode side of metal redox barrier 410 and dissolves on the cathode side, a net thickness of the plate may not change substantially same over time. However, metal redox barrier 410 may migrate over time towards inert anode 404. Thus, in some examples, one or more mechanical bias elements 440 may be used to bias metal redox barrier 410 toward the intermediate chamber 412. As an example, mechanical bias element 440 may comprise a spring mechanism to bias the position of metal redox barrier 410. This may help to maintain a suitably consistent distance between substrate 430 and metal redox barrier 410. To prevent bubbles and acid from migrating around the sides of metal redox barrier 410, suitable seals 442 may be used.

Metal redox barrier 410 may not deplete or replenish evenly across both surfaces over time. Thus, metal redox barrier 410 may be replaced on occasion. However, the replacement of metal redox barrier 410 may occur at a lower frequency than for an active anode. As such, the use of metal redox barrier 410 may lead to less downtime than the use of an active anode. Further, replacing metal redox barrier 410 may be less time consuming and less costly than replacing an active anode. Relatively thicker metal films may be plated onto a substrate without concerns of anode passivation due to precipitates generated from increased local concentrations of metal ions. Also, bubbles emanating from inert anode 404 are prevented from reaching cation exchange membrane 418. This may help to avoid the impact on plating uniformity of bubbles gathering on cation exchange membrane 418. The management of concentrations of chemical species also may be facilitated by the metal being consumed and released continuously in the presence of an electric field.

In the example of FIG. 4, one or more mechanical bias elements are used to maintain a suitably consistent spacing between metal redox barrier 410 and cation exchange membrane 418. In other examples, a metal redox barrier may be rotated periodically. Rotating a metal redox barrier allows surfaces of the metal redox barrier to be exposed both to oxidation and reduction over time.

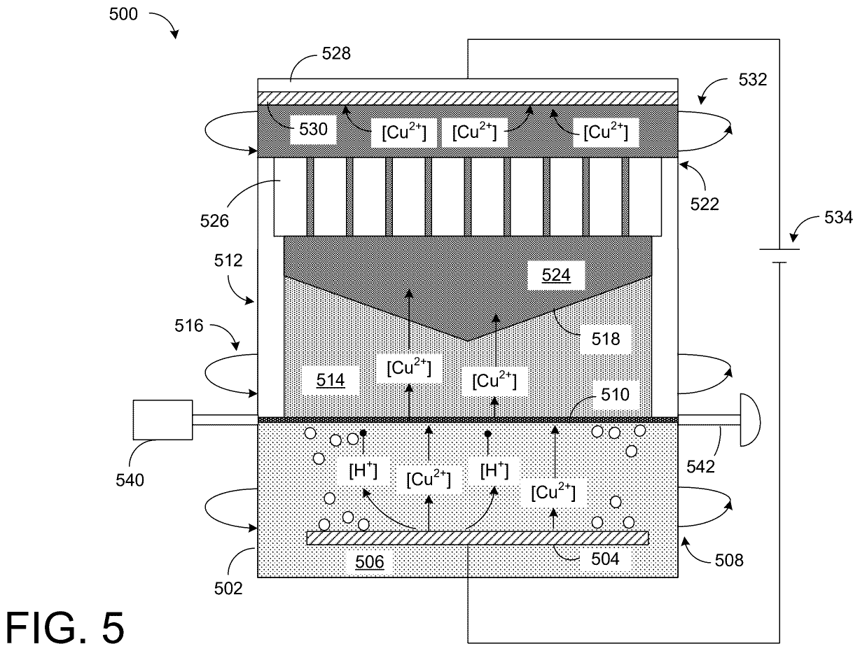

FIG. 5 shows an example of an electrodeposition system 500 comprising a metal redox barrier 510 (e.g., a rotatable metal redox barrier). Electrodeposition system 500 is an example of electrodeposition system 300. Briefly, electrodeposition system 500 includes an anode chamber 502 comprising an inert anode 504. Anode chamber 502 is configured to hold an anolyte bath 506 that may be replenished via anolyte circulation loop 508.

A metal redox barrier 510 separates an intermediate chamber 512 from anode chamber 502. Intermediate chamber 512 may be configured to hold an intermediate bath 514. Intermediate bath 514 may be replenished via intermediate bath circulating loop 516.

Cation exchange membrane 518 separates intermediate chamber 512 from cathode chamber 522. Cation exchange membrane 518 allows selective transport of cations between intermediate bath 514 and catholyte bath 524. Cathode chamber 522 further includes a HRVA 526 and a substrate holder 528. A substrate 530 comprising a cathode layer may be positioned in substrate holder 528 and exposed to catholyte bath 524 during an electrodeposition process. Catholyte bath 524 may be replenished via catholyte circulating loop 532. A voltage source 534 may apply a voltage across inert anode 504 and substrate 530 to drive the electrodeposition process.

Metal redox barrier 510 is rotatable so that the anode side and cathode side of the plate may alternate their respective orientations toward intermediate chamber 512. In some examples, metal redox barrier 510 may be manually rotated by an operator. In other examples, metal redox barrier 510 may be automatically rotated. For example, FIG. 5 shows metal redox barrier 510 rotatably coupled to motor box 540 via axis 542.

Electrodeposition system 500 may plate metal on the anode side of metal redox barrier 510 for one or more plating cycles. Then, electrodeposition system 500 may rotate metal redox barrier 510 so that the recently plated metal side may undergo oxidation on one or more plating cycles. In some examples, an amount of metal consumed may be monitored. Then, metal redox barrier 510 may be rotated when the metal consumed reaches a threshold. In some examples, metal redox barrier 510 may be rotated when a substrate is being rinsed, or during other ordinary electrodeposition system processes. This may help to avoid downtime while rotating metal redox barrier 510. Further, catholyte bath 524 may be undisturbed by rotating metal redox barrier 510.

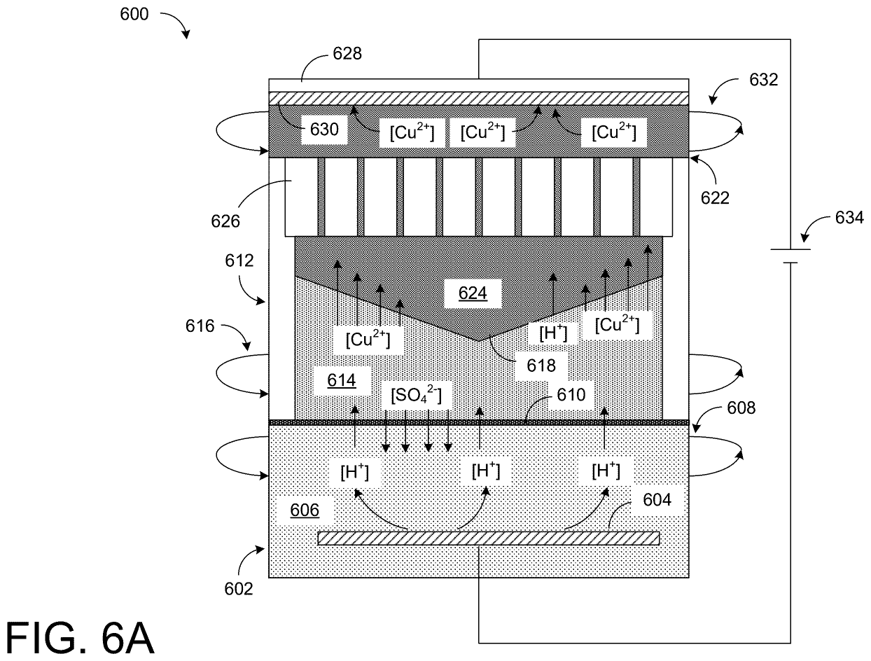

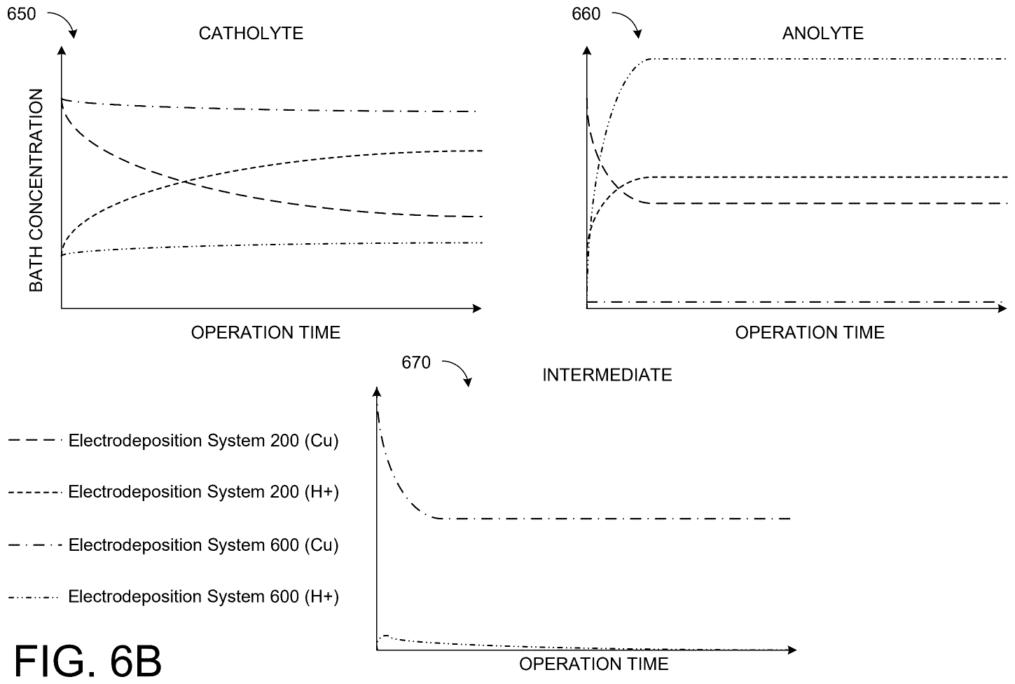

As mentioned above with regard to FIG. 3, in some examples, an ion exchange membrane may be used as a proton-impeding structure. FIG. 6A shows an example electrodeposition system 600 comprising an anion exchange membrane as a proton-impeding structure. Electrodeposition system 600 may be an example of electrodeposition system 300. Briefly, electrodeposition system 600 includes an anode chamber 602 comprising an inert anode 604. Anode chamber 602 is configured to hold an anolyte bath 606 that may be replenished via anolyte circulation loop 608.

An anion exchange membrane 610 separates intermediate chamber 612 from anode chamber 602. Intermediate chamber 612 may be configured to hold an intermediate bath 614. Intermediate bath 614 may be replenished via intermediate bath circulating loop 616.

A cation exchange membrane 618 separates intermediate chamber 612 from cathode chamber 622. Cation exchange membrane 618 allows selective transport of cations between intermediate bath 614 and catholyte bath 624. Cathode chamber 622 further includes a HRVA 626 and a substrate holder 628. A substrate 630 comprising a cathode layer may be positioned in substrate holder 628 and exposed to catholyte bath 624 during an electrodeposition process. Catholyte bath 624 may be replenished via catholyte circulating loop 632. Voltage source 634 may apply a voltage across inert anode 604 and substrate 630 to drive the electrodeposition process.

Electrodeposition system 600 is described with regard to a Cu plating process. However, in other examples, any other suitable metal plating processes may be performed using electrodeposition system 600. In this example, mass imbalance issues that may arise from using an inert anode are addressed.

Anolyte bath 606 may comprise a dilute acid (e.g., H₂SO₄). In some examples, anolyte bath 606 may include metal ions. However, any included metal ions are not used to supply metal ions for plating substrate 630.

Anion exchange membrane 610 separates anode chamber 602 and intermediate chamber 612. Anion exchange membrane may preferentially pass negatively charged species (e.g. SO₄²⁻) from intermediate chamber 612 to anode chamber 602. Further, electrolysis of water occurs at inert anode 604. Thus, H₂SO₄ is generated inside the anode chamber. Cation exchange membrane 618 may preferentially pass positively charged species (e.g., protons and metal ions) across the membrane from intermediate chamber 612 to cathode chamber 622.

Intermediate bath 614 supplies at least some metal ions for plating in the form of metal salt. In the depicted example, intermediate bath 614 comprises the metal salt CuSO₄. In other examples, any other suitable cations and/or anions may be used. Anion exchange membrane 610 and cation exchange membrane 618 may be selected to match selected ion chemistries, and/or may be conditioned on appropriate solutions before being implemented.

Intermediate bath 614 and catholyte bath 624 may comprise the same chemistries, such as a same metal salt. In some examples, intermediate bath 614 may comprise a different concentration of metal salt (e.g. copper sulfate than catholyte bath 624. In other examples, intermediate bath 614 and catholyte bath 624 may comprise any suitable chemical differences.

With cation exchange membrane 618 positioned between cathode chamber 622 and intermediate chamber 612, Cu²⁺ migrates from intermediate chamber 612 to cathode chamber 622. Combined with the reduction reaction happening on the surface of substrate 630, catholyte Cu concentration may be maintained at a suitably consistent level.

However, Cu²⁺ passing from intermediate chamber 612 through cation exchange membrane 618 to cathode chamber 622, combined with SO₄²⁻ passing through anionic exchange membrane 610 to anode chamber 602, depletes CuSO₄ in intermediate chamber 612. As such, intermediate chamber 612 may be replenished with CuSO₄. Replenishment may be performed by recirculating the intermediate bath 614 through solid CuSO₄ crystals via intermediate bath circulating loop 616, or by adding concentrated salt solution, as examples.

The use of copper sulfate in intermediate bath 614 may provide a less expensive source of copper ions than a high purity solid Cu active anode. Further, no anode replacement is needed. Further, the supply of Cu ions through a solution may not generate particle contaminants. In contrast, an active anode may generate particle contaminants. As such, the use of copper sulfate intermediate bath 614 may allow the use of a simplified anolyte bath filtration system.

Unlike the two-chamber, one-membrane design described with regard to FIG. 2, the combined charge transfer effect of cation exchange membrane 618 and the anionic exchange membrane 610 may mass-balance both metal ions and protons in the catholyte bath 624. This may lead to more stable catholyte bath concentrations. In this way, the mass balance of catholyte bath 624 can be maintained without undue effort during an electrochemical plating process.

Cation exchange membrane 618 and anion exchange membrane 610 may occasionally be replaced. However, such maintenance may be less frequent than replacement of an active anode.

FIG. 6B shows example solution concentrations of copper ions and protons over time in the electrodeposition system 200 of FIG. 2 compared to electrodeposition system 600 of FIG. 6A. At 650, ion concentrations for example catholyte baths are shown over a period of operation time for the respective electrodeposition systems. At 660, ion concentrations for example anolyte baths are shown over a period of operation time for the respective electrodeposition systems. At 670, ion concentrations for an example intermediate bath (e.g., intermediate bath 614) are shown.

In electrodeposition system 200, protons are continuously generated and accumulated in the anode chamber, as shown at 660. Further, the protons cross over the cationic membrane to the cathode side. The net effect over time on the catholyte bath is Cu ion depletion and acid accumulation, as shown at 650. The drift in concentration may lead to issues in plating processes, such as defects. In contrast, for electrodeposition system 600, the increase in acid in the anode chamber is buffered from the cathode chamber. Further, the copper plated at the substrate is continuously replenished from the intermediate bath. Thus, the combined usage of both a cationic membrane and anionic membrane in an electrochemical plating system may balance the mass between acid and metal ions. Further, both Cu ion and proton concentrations on the cathode side may be stable over time.

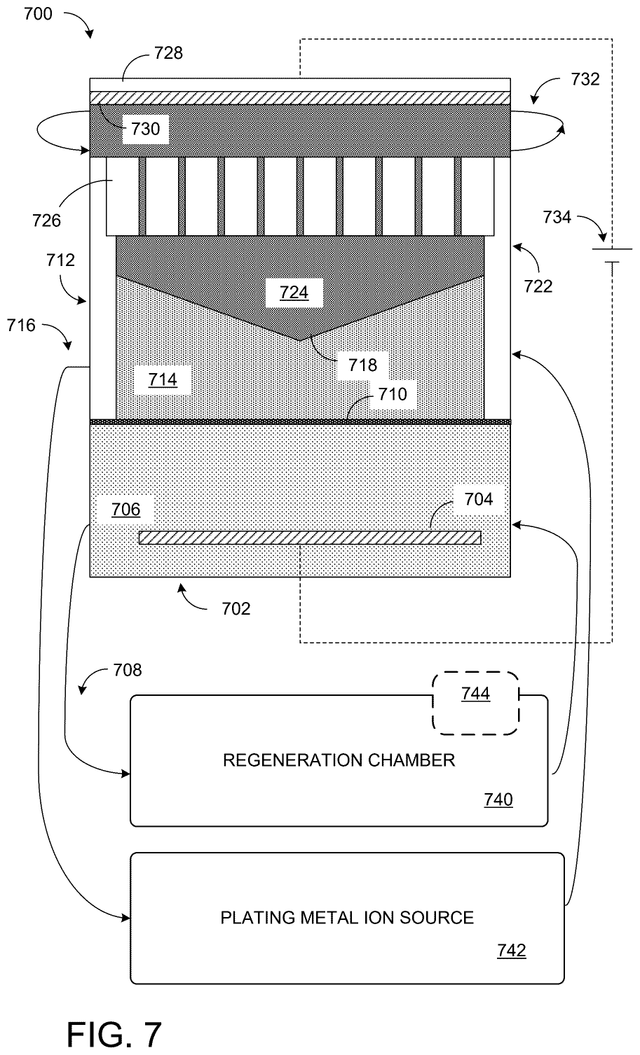

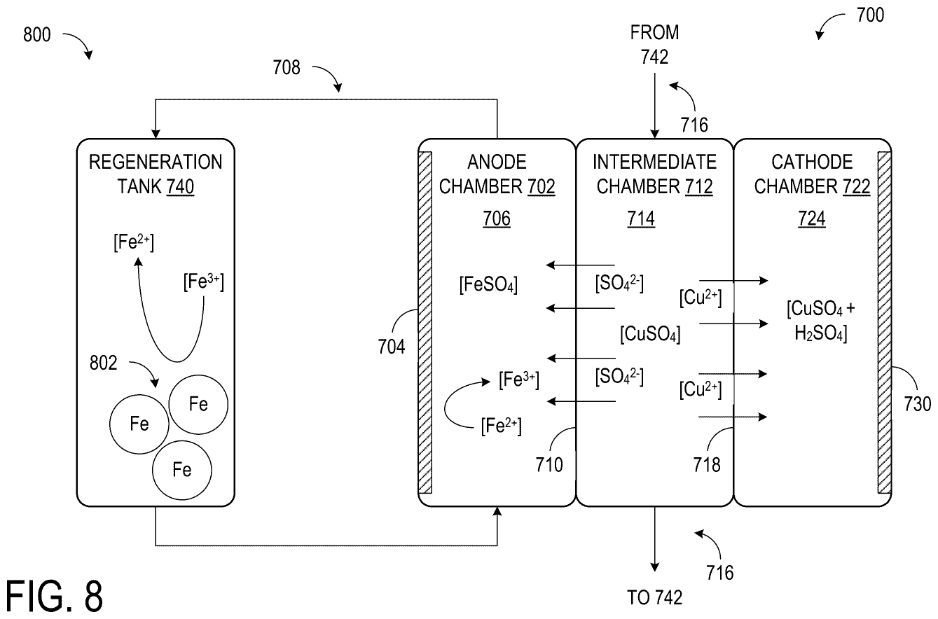

To further address proton generation and bath management, a redox shuttle system may be utilized where a redox couple is used to avoid the electrolysis of water in the anolyte. FIG. 7 shows an example of an electrodeposition system 700 comprising an anion exchange membrane as a proton-impeding structure, a cation exchange membrane as an ion exchange membrane, and a redox shuttle circulation system configured to provide a redox shuttle species to the anode chamber. FIG. 8 schematically shows an example of a redox chemistry that may be used with electrodeposition system 700.

Briefly, electrodeposition system 700 comprises an anode chamber 702 comprising an inert anode 704. Anode chamber 702 is configured to hold an anolyte bath 706 that may be replenished via redox shuttle circulation system 708. Electrodeposition system 700 further comprises an anion exchange membrane separating intermediate chamber 712 from anode chamber 702. Intermediate chamber 712 may be configured to hold an intermediate bath 714. Intermediate bath 714 may be replenished via intermediate bath circulating loop 716.

Cation exchange membrane 718 separates intermediate chamber 712 from cathode chamber 722. Cation exchange membrane 718 allows selective transport of ions between intermediate bath 714 and catholyte bath 724. Cathode chamber 722 further includes a HRVA 726 and a substrate holder 728. A substrate 730 comprising a cathode layer may be positioned in substrate holder 728 and exposed to catholyte bath 724 during an electrodeposition process. Catholyte bath 724 may be replenished via catholyte circulating loop 732, which may include hardware features to control temperature, water balance, organic additive concentration, etc. Voltage source 734 may apply a voltage across inert anode 704 and substrate 730 to drive the electrodeposition process.

Redox shuttle circulation system 708 may be configured to provide a redox shuttle species to anode chamber 702. Redox shuttle circulation system 708 further may comprise a regeneration chamber 740 (e.g., redox shuttle species regeneration chamber). Intermediate bath circulating loop 716 may include a plating metal ion source 742, such as a supply of concentrated copper sulfate for copper plating reactions. In some examples, the intermediate chamber may be omitted. Anode chamber 702 may be separated from cathode chamber 722 by a first ion exchange membrane, such as an anion exchange membrane 710.

Referring to FIG. 8, an example of the operation and chemistry of electrodeposition system 700 is described in the context of copper plating. In this example, Fe²⁺/Fe³⁺ ions may be added to anolyte bath 706 as part of a redox shuttle. The oxidation potential of Fe²⁺ is 700 mV lower than that of water. As a result, the oxidation reaction on inert anode 704 is biased away from oxygen and proton formation towards an oxidation reaction that oxidizes ferrous irons (Fe²⁺) to form ferric irons (Fe³⁺). The oxidized Fe³⁺ ions may be reduced back to Fe²⁺ separately via regeneration chamber 740, which comprises a source of electrons, such as a metal suited for galvanic reactions. The regenerated Fe²⁺ may then be fed back to anode chamber 702 via redox shuttle circulation system 708.

In other examples, any other suitable redox couple may be used other than iron. Suitable redox couples include species having an oxidation potential of the redox couple lower than that for oxygen evolution. For example, the potential difference between the ferric reaction and the regenerative metal reaction may be at least 300 millivolts. If the total potential difference is positive, then the AG becomes positive and the shuttle reaction becomes spontaneous.

In the depicted example, Fe³⁺ has a reduction potential of 0.77 V. As such, any metal or element with a positive oxidation potential or a reduction potential lower than 0.77 V may be used as the redox couple. Such elements may include copper, sulfur, lead, tin, nickel, cobalt, zinc, manganese, aluminum, and magnesium, as examples.

For regeneration of the reduced ion species, regeneration chamber 740 may include a metal or other electron donor that can undergo a favorable galvanic reaction. In the example shown in FIG. 8, iron metal 802 is used. Note that the metal used for regeneration may be different than the metal used for plating. However, in some examples the plating metal (e.g., copper) may be used for regeneration. In some examples, regeneration chamber 740 includes an oxygen removal stage 744.

In this configuration, the three chambers of electrodeposition system 700 are generated by positioning anion exchange membrane 710 between anode chamber 702 and intermediate chamber 712, and by positioning cation exchange membrane 718 between intermediate chamber 712 and cathode chamber 722. As shown at 800 of FIG. 8, anolyte bath 706 includes ferrous sulfate. In this example, copper sulfate is included in intermediate bath 714, and a low acid solution is included in catholyte bath 724 (e.g., a mixture including copper sulfate, sulfuric acid, and chloride).

As little acid is generated at inert anode 704, there is no associated increase in acid concentration over operation time in either intermediate bath 714 or catholyte bath 724. The majority of charge is carried by copper ions to cathode chamber 722 from intermediate chamber 712. This replenishes plated copper and maintains the copper concentration within catholyte bath 724. While described with regard to copper, a redox shuttle may be used to avoid acid production in any other suitable electrodeposition process.

As described above, the use of an inert anode may lower preventive maintenance costs as compared to using a consumable anode. Plating thus may be performed at an increased current without causing anode passivation. Further, little or no acid is generated in the anolyte chamber, leading to simplified bath management. Bubble generation is kept low, and thus does not interfere in the electrical path. As the solutions are isolated and contained using membranes, plating uniformity may be maintained.

Over time, the concentration of the regeneration species may increase in redox shuttle circulation system 708. For example, copper metal over time may builds up as copper sulfate. As another example, iron may build up as iron sulfate. In some examples, an additional species of metal may also be included in order to galvanically extract the dissolved regeneration species (e.g., Cu²⁺) from the anolyte solution. For some regeneration species, such as iron, some hydrogen may be generated in solution, allowing for control of acid concentrations in regeneration chamber 740 without leading to bubbles in the anode chamber itself.

In some examples, anode chamber oxygen concentration may be regulated to prevent the generation of metal oxide precipitates (e.g., ferrous oxide) within anode chamber 702. In some such examples, anode chamber 702 may be backfilled with inert gas, thus reducing the dissolved oxygen concentration in the entire electrodeposition system 700. Regeneration chamber 740 may optionally include an oxygen removal stage 744 for removing oxygen from the system.

Over time, iron ions are dissolved from iron metal 802 into the anolyte bath 706. Further, copper ions are plated onto substrate 730 from catholyte bath 724. However, with an anion exchange membrane 710 separating anode chamber 702 and intermediate chamber 712, the iron ions from iron metal 802 are not passed into intermediate chamber 712 or cathode chamber 722. Rather, the copper that is plated comes from intermediate chamber 712 via plating metal ion source 742.

As minimal acid is being formed at inert anode 704, the conductivity across electrodeposition system 700 increases only modestly over time. Any conductivity increase may be predominantly due to increases in metal ion concentrations from redox shuttle circulation system 708.

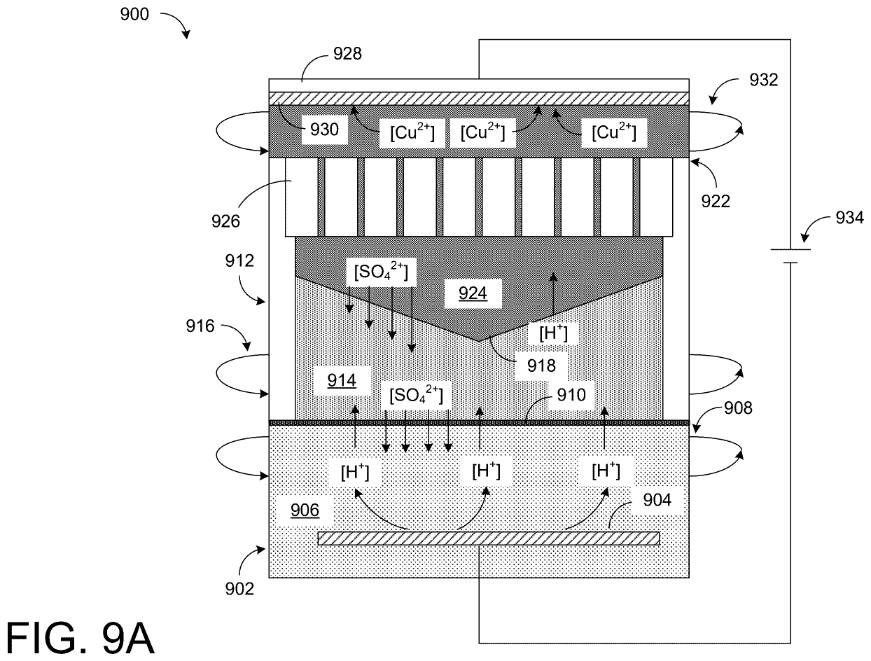

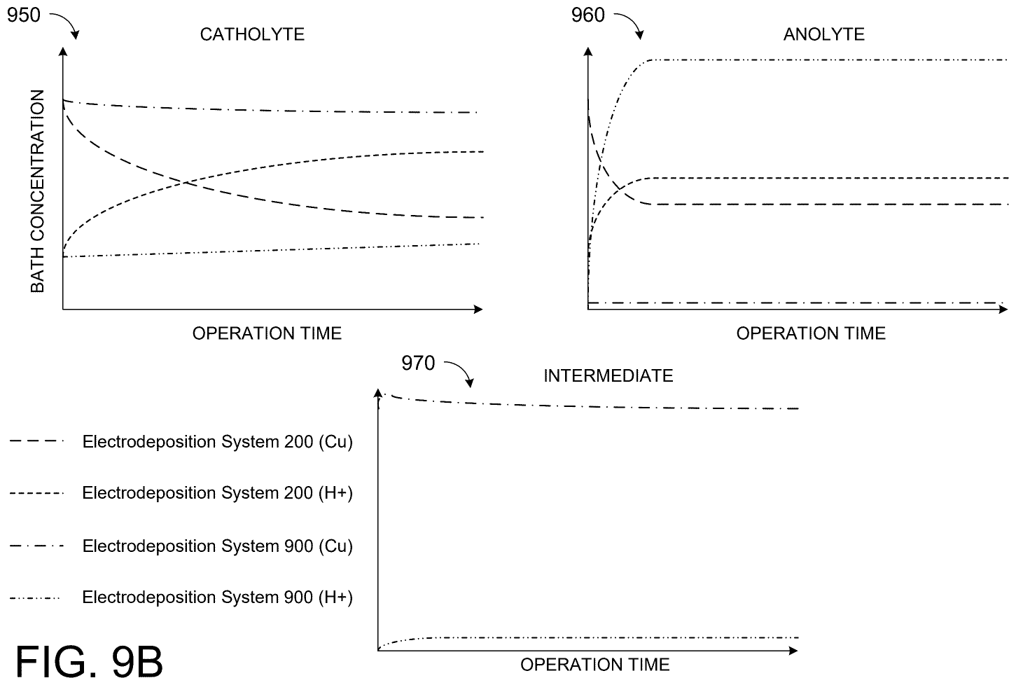

FIG. 9A shows an electrodeposition system 900 that utilizes an alternative approach to address mass imbalance issues from utilizing an inert anode. FIG. 9A again uses a three-chamber design. However, instead of utilizing an anion exchange membrane between the anode and intermediate chambers along with a cation exchange membrane between the intermediate and cathode chambers, electrodeposition system 900 utilizes two layers of anion exchange membrane.

More particularly, electrodeposition system 900 includes an anode chamber 902 comprising an inert anode 904. Anode chamber 902 is configured to hold an anolyte bath 906 that may be replenished via circulation loop 908 (e.g., anolyte circulation loop).

A first anion exchange membrane 910 may separate intermediate chamber 912 from anode chamber 902. Intermediate chamber 912 may be configured to hold an intermediate bath 914, which may be replenished via intermediate bath circulating loop 916. A second anion exchange membrane 918 separates intermediate chamber 912 from cathode chamber 922, allowing selective transport of ions between intermediate bath 914 and catholyte bath 924. Cathode chamber 922 further includes a HRVA 926 and a substrate holder 928. A substrate 930 comprising a cathode layer may be positioned in substrate holder 928 and exposed to catholyte bath 924 during an electrodeposition process. Catholyte bath 924 may be replenished via catholyte circulating loop 932 Voltage source 934 may apply a voltage across inert anode 904 and substrate 930 to drive the electrodeposition process.

As compared to the example of FIG. 6A, the electrodeposition system of FIG. 9A may provide more consistent acid concentration bath maintenance. This is at least for the reason that the anion exchange membrane material may pass a quantity of protons despite anions being the preferred charge transfer species. By adding second anion exchange membrane 918 between inert anode 904 and substrate 930, direct transfer of protons from the proton-rich anode chamber 902 into cathode chamber 922 is mitigated. Instead, protons are carried into intermediate chamber 912. When charge is carried across second anion exchange membrane 918 between intermediate chamber 912 and cathode chamber 922, the selective preference for SO₄²⁻ over protons helps to limit a number of protons entering cathode chamber 922, maintaining the acid balance in catholyte bath 924.

Water is electrolyzed into H⁺ and O₂ in anode chamber 902, and copper is reduced on substrate 930. Sulfate migrates across the first anion exchange membrane 910 into anode chamber 902. Copper migrates from intermediate chamber 912 across second anion exchange membrane 918 to cathode chamber 922 to complete the electrical circuit. As hydrogen evolves, sulfate enters anode chamber 902 as a form of charge balance, and to reduce migration pressure. The sulfate concentration increases over time, retaining protons as sulfuric acid in anode chamber 902. This acidification may be countered through water doping via anolyte bath circulating loop 908 to maintain the acid concentration at a desired level. Copper plated from catholyte bath 924 is replenished from intermediate chamber 912 across second anion exchange membrane 918.

Copper sulfate may become depleted from intermediate chamber 912. Thus, copper sulfate may be replenished via intermediate bath circulating loop 916. Some quantity of protons will migrate out of anode chamber 902 to some extent regardless of the membrane selectivity. The balance of acid may be maintained by having a suitably consistent supply of copper sulfate in intermediate chamber 912. If the pH of intermediate bath 914 is kept low enough and water is introduced into anolyte bath circulating loop 908, proton migration may be maintained at a suitably low level.

FIG. 9B shows example solution concentrations of copper ions and protons over time in the electrodeposition system 200 of FIG. 2 compared to electrodeposition system 900 of FIG. 9A. At 950, ion concentrations for example catholyte baths are shown over a period of operation time for the respective electrodeposition tool. At 960, ion concentrations for example anolyte baths are shown over a period of operation time for the respective electrodeposition tool. At 970, ion concentrations for an intermediate bath (e.g., intermediate bath 914) are shown.

All three baths display steady concentrations once the steady-state is reached. Plating operations may thus be commenced as soon as the cathode chamber copper concentration is in a predetermined concentration range. Even at time zero, there may be enough copper for the plating reaction, as long as the acid concentration is within the desired range. As shown at 950 and 960, even if there is a lot of acid generated at the anode, the protons concentration remains relatively low and constant in the catholyte bath.

FIG. 10 shows an example of an electrodeposition system 1000 comprising a cation exchange membrane as a proton-impeding structure and a cation exchange membrane as an ion exchange membrane. Electrodeposition system 1000 may be an example of electrodeposition system 300. Briefly, electrodeposition system 1000 includes an anode chamber 1002 comprising an inert anode 1004. Anode chamber 1002 is configured to hold an anolyte bath 1006 that may be replenished via anolyte circulation loop 1008.

A first cation exchange membrane 1010 may separate intermediate chamber 1012 from anode chamber 1002. Intermediate chamber 1012 may be configured to hold an intermediate bath 1014. Intermediate bath 1014 may be replenished via intermediate bath circulating loop 1016.

A second cation exchange membrane 1018 separates intermediate chamber 1012 from cathode chamber 1022. Second cation exchange membrane 1018 allows selective transport of ions between intermediate bath 1014 and catholyte bath 1024. Cathode chamber 1022 further includes a HRVA 1026 and a substrate holder 1028. A substrate 1030 comprising a cathode layer may be positioned in substrate holder 1028 and exposed to catholyte bath 1024 during an electrodeposition process. Catholyte bath 1024 may be replenished via catholyte circulating loop 1032. Voltage source 1034 may apply a voltage across inert anode 1004 and substrate 1030 to drive the electrodeposition process.

At inert anode 1004, protons are generated and carried across first cation exchange membrane 1010 into intermediate bath 1014. In this example, intermediate bath circulating loop 1016 includes a copper oxide module 1040. CuSO₄ and H₂SO₄ exit intermediate chamber 1012. Protons from the H₂SO₄ react with the Cup in copper oxide module 1040 to generate Cu²⁺ and H₂O. In this way, the protons transported into intermediate bath 1014 are exchanged for copper, replenishing copper that moves across second cation exchange membrane 1018 into catholyte bath 1024. This may help to provide a suitably stable concentration of copper for catholyte bath 1024. In some examples, anolyte circulation loop 1008 may dose anolyte bath 1006 with a low acid solution to further manage the acid generated by inert anode 1004. In some examples, the intermediate chamber may be omitted. Anode chamber 1002 may be separated from cathode chamber 1022 by a single cation exchange membrane, e.g., second cation exchange membrane 1018 such that copper oxide module 1040 is fluidly coupled to anode chamber 1002.

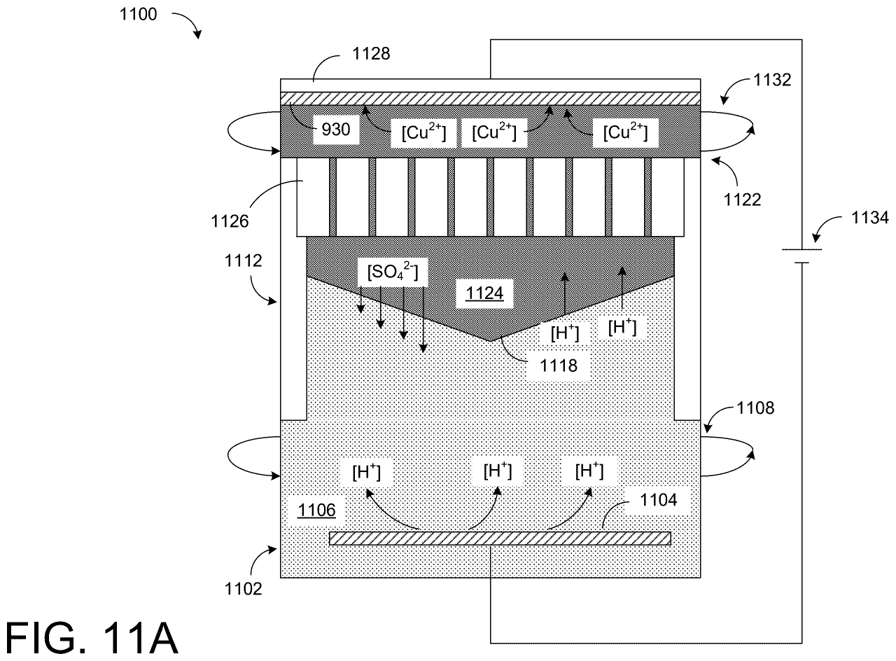

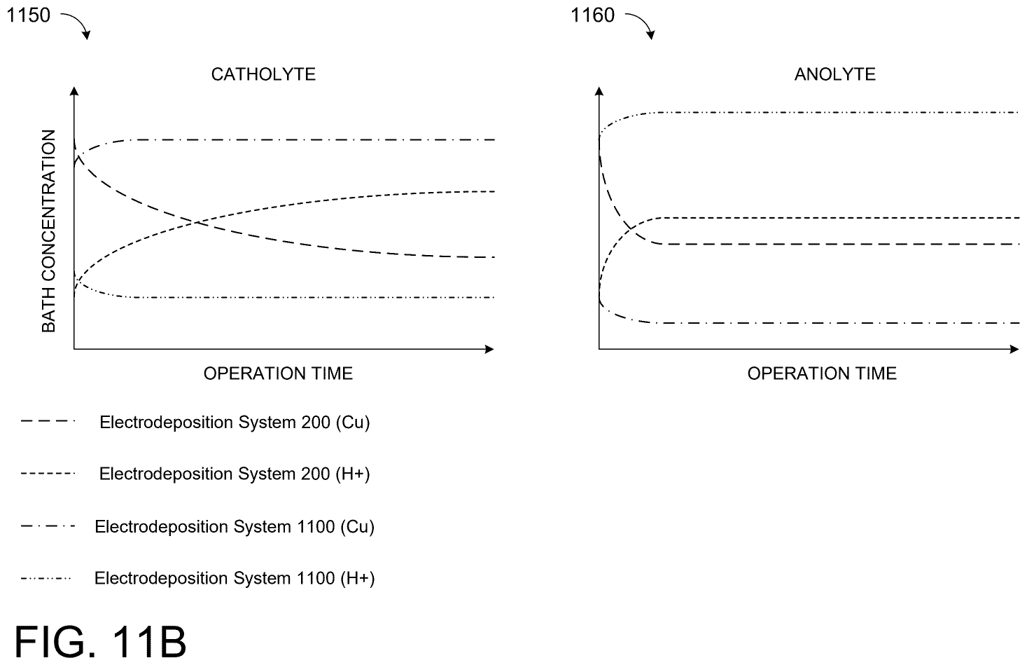

In another example, the problems of mass balance and catholyte acidification may be addressed by using an anion exchange membrane. FIG. 11A shows an example of an electrodeposition system 1100 comprising an anion exchange membrane and no cation exchange membrane or other proton-impeding structure. Briefly, electrodeposition system 1100 includes an anode chamber 1102 comprising an inert anode 1104. Anode chamber 1102 is configured to hold an anolyte bath 1106 that may be replenished via anolyte circulation loop 1108. Electrodeposition system 1100 is similar in structure to electrodeposition system 200, but replaces the cation exchange membrane 206 with an anion exchange membrane 1118.

Anion exchange membrane 1118 separates anode chamber 1102 from cathode chamber 1122. Anion exchange membrane 1118 allows selective transport of ions between anolyte bath 1106 and catholyte bath 1124. Cathode chamber 1122 further includes a HRVA 1126 and a substrate holder 1128. A substrate 1130 comprising a cathode layer may be positioned in substrate holder 1128 and exposed to catholyte bath 1124 during an electrodeposition process. Catholyte bath 1124 may be replenished via catholyte circulating loop 1132. Voltage source 1134 may apply a voltage across inert anode 604 and substrate 630 to drive the electrodeposition process.

As shown, protons generated at inert anode 1104 can cross anion exchange membrane 1118 into cathode chamber 1122, but at a relatively low rate. Sulfate from catholyte bath 1124 does cross anion exchange membrane 1118, forming H₂SO₄ in anolyte bath 1106. Copper is maintained in cathode chamber 1122 by anion exchange membrane 1118, and may be replenished through copper sulfate via catholyte circulating loop 1132.

The end effect of the above processes on solution concentrations is illustrated in FIG. 11B. FIG. 11B shows example solution concentrations of copper ions and protons over time in the electrodeposition system 200 of FIG. 2 compared to electrodeposition system 1100 of FIG. 11A. At 1150, ion concentrations for example catholyte baths are shown over a period of operation time for the respective electrodeposition tool. At 1160, ion concentrations for example anolyte baths are shown over a period of operation time for the respective electrodeposition tool. As shown, the use of an anion exchange membrane may provide for more consistent ion concentrations compared to the use of a cation exchange membrane. In particular, ion concentrations in the catholyte bath stabilize relatively quickly for an electrodeposition system utilizing an anion exchange membrane, as shown at 1150.

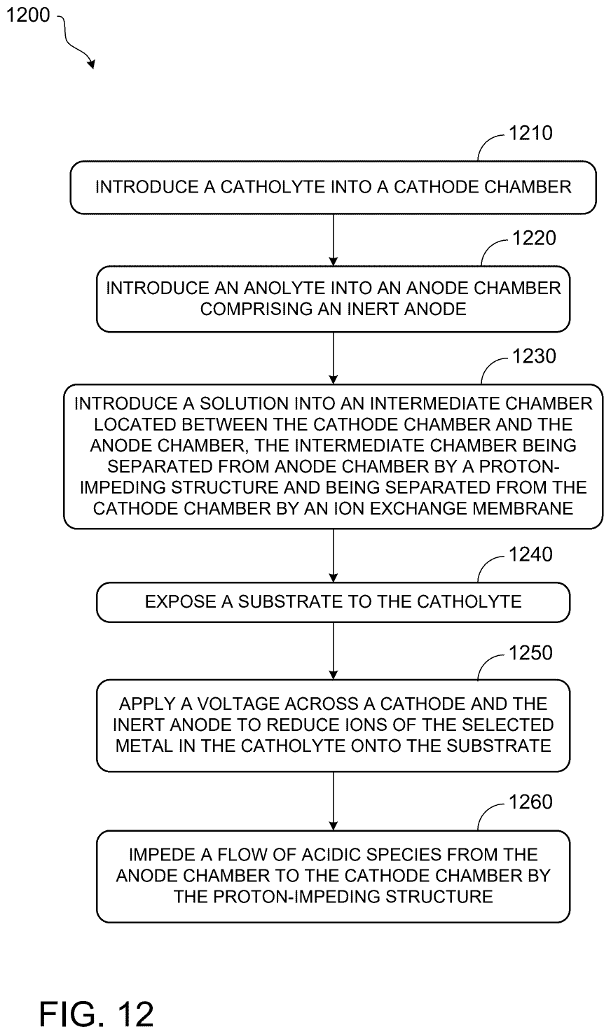

FIG. 12 shows a flow diagram depicting an example method 1200 for forming a layer of a selected metal material on a substrate by electrodeposition. Method 1200 may be executed by a controller, such as computing system 150, that is communicatively coupled to an electrodeposition system, such as electrodeposition system 300.

At 1210, method 1200 includes introducing a catholyte into a cathode chamber, for example, by a catholyte circulating loop. The catholyte may include at least a supply of metal ions for electrodeposition on the substrate. At 1220, method 1200 includes introducing an anolyte into an anode chamber comprising an inert anode, for example, by an anolyte circulating loop. As described with regard to FIGS. 4 and 5, the anolyte may include the metal ions for electrodeposition on the substrate. Alternatively, as described with regard to FIGS. 9A and 10, the anolyte may include a dilute acid solution with counter ions selected based on an overall chemistry of the electrodeposition system.

At 1230, method 1200 includes introducing a solution into an intermediate chamber located between the cathode chamber and the anode chamber, the intermediate chamber being separated from anode chamber by a proton-impeding structure and being separated from the cathode chamber by an ion exchange membrane. The solution introduced into the intermediate chamber (e.g., intermediate bath) may be introduced by an intermediate bath circulating loop, which in some examples may be fluidly coupled to a source of metal ions for plating.

In some examples, the proton-impeding structure comprises a metal barrier comprising the selected metal, as described with regard to FIGS. 4 and 5. The proton-impeding structure may alternatively comprise an anion exchange membrane, as described with regard to FIGS. 7, 8, and 9A or a cation exchange membrane, as described with regard to FIGS. 6A and 10.

At 1240, method 1200 includes exposing a substrate to the catholyte, for example, by positioning a substrate holder into the cathode chamber. At 1250, method 1200 includes applying a voltage across a cathode and the inert anode to reduce ions of the selected metal in the catholyte onto the substrate.

At 1260, method 1200 includes impeding a flow of acidic species from the anode chamber to the cathode chamber by the proton-impeding structure. Where the proton-impeding structure comprises a metal barrier comprising the selected metal, the method may comprise depositing a film of the selected metal onto an anode side of the metal redox barrier by reduction of ions of the selected metal from anolyte. Such an example may further comprise oxidizing a cathode side of the metal redox barrier to form ions of the selected metal in the intermediate chamber. In some such examples, the method may further comprise biasing the metal redox barrier toward the intermediate chamber. The ions of the selected metal in the intermediate chamber may pass through the ion exchange membrane to the cathode chamber.

In examples wherein the proton-impeding structure comprises an anion exchange membrane, the ion exchange membrane separating the intermediate chamber and the cathode chamber may comprise a cation exchange membrane. In such examples, the method may further comprise flowing an intermediate chamber solution through the intermediate chamber, the intermediate chamber solution comprising a salt of the selected metal.

In some examples, the proton-impeding structure comprises a cation exchange membrane, and the ion exchange membrane separating the intermediate chamber and the cathode chamber comprises a cation exchange membrane. In such examples, the method may further comprises flowing an intermediate chamber solution through the intermediate chamber, the intermediate chamber solution comprising a salt of the selected metal.

In some examples the proton-impeding structure comprises an ion exchange membrane. In such examples, the electrodeposition system may further comprise a redox shuttle circulation system configured to provide a redox shuttle species in the anolyte to the anode chamber. In such examples, the method may further comprise flowing the anolyte through a redox shuttle species regeneration chamber.

Examples also are disclosed that relate to bubble management in an electrodeposition system. Briefly, the disclosed examples utilize an inert anode assembly with anolyte flow channels that are configured to flow an anolyte with a sufficient linear flow velocity to reduce bubble accumulation beneath an ion exchange membrane. As described in more detail below, the disclosed example inert anode assemblies may be more compact than conventional anode chambers in an electrodeposition system. Further, the disclosed example inert anode assemblies also may help to reduce an anolyte flow volume compared to conventional anode chambers.

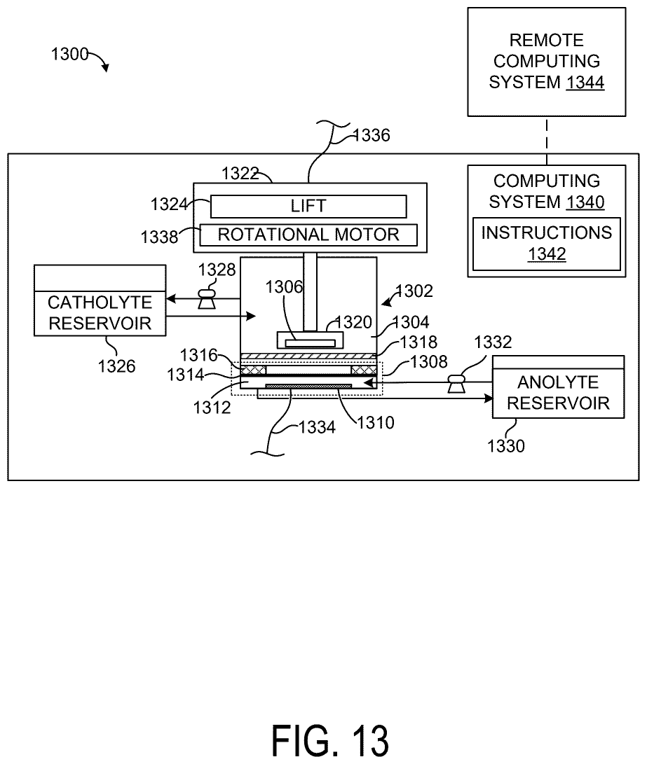

FIG. 13 schematically shows a block diagram of another example electrodeposition system 1300. Electrodeposition system 1300 comprises an electrodeposition cell 1302 comprising a cathode chamber 1304. Cathode chamber 1304 holds a catholyte. The catholyte comprises an ionic species to be deposited on a cathode layer of a substrate 1306 as a metal by electrochemical reduction.

Electrodeposition cell 1302 further comprises an inert anode assembly 1308. Inert anode assembly 1308 comprises an inert anode 1310 and an anolyte channel component 1312. Anolyte flow channels formed in anolyte channel component 1312 restrict anolyte flow to segmented areas during an electrodeposition process.

An ion exchange membrane 1314 is positioned between a cathode chamber bottom component 1316 and anolyte channel component 1312. In various examples, ion exchange membrane 1314 may comprise a cation exchange membrane or an anion exchange membrane. Electrodeposition system 1300 further comprises a high resistance virtual anode (HRVA) 1318 within cathode chamber 1304. HRVA 1318 comprises an ionically resistive element that approximates a suitably constant and uniform current source in proximity to a substrate cathode.

A substrate holder 1320 exposes substrate 1306 to the catholyte during the electrodeposition process. Further, substrate holder 1320 is coupled to a substrate holder movement system 1322. Substrate holder movement system 1322 comprises a lift 1324 configured to adjust a position of substrate holder 1320. For example, lift 1324 lowers substrate holder 1320 to position substrate 1306 within the catholyte for electrodeposition. Lift 1324 further raises substrate holder 1320 from the catholyte after electrodeposition. Substrate holder movement system 1322 further comprises components to control the opening and closing of substrate holder 1320.

The catholyte is circulated between cathode chamber 1304 and a catholyte reservoir 1326 using a combination of gravity and one or more pumps 1328. Likewise, the anolyte is circulated through anolyte reservoir 1330 and the anolyte flow channels of anolyte channel component 1312 using a combination of gravity and one or more pumps 1332. Bulk anolyte and/or catholyte solutions may be added at times to replenish and/or rebalance ionic species.

In some electrodeposition systems, plating operations may be performed in parallel on multiple substrates using multiple plating cells. In some such examples, central catholyte and/or anolyte reservoirs may supply multiple plating cells with catholyte and/or anolyte. In other such examples, separate catholyte and/or anolyte reservoirs may be used to supply multiple plating cells. In yet other examples, an electrodeposition system may comprise a single plating cell. Where an electrodeposition system comprises multiple plating cells, a single lift may be configured to lift two or more substrate holders for two or more different plating cells.

Substrate holder 1320 is lowered by lift 1324 toward HRVA 1318 after substrate 1306 is loaded into substrate holder 1320. Substrate 1306 faces a surface of the HRVA 1318, and is spaced from HRVA 1318 by a plating gap during electrodeposition. An electric field is established between inert anode 1310 and substrate 1306. This electric field drives dissolved metal cations towards substrate 1306. At substrate 1306, the metal cations are electrochemically reduced to deposit a metal film on substrate 1306. An anodic potential is applied to inert anode 1310 using an anode electrical connection 1334 and a cathodic potential is provided to the cathode of substrate 1306 using a cathode electrical connection 1336 to form a circuit. In some examples, substrate holder 1320 may be rotated using a rotational motor 1338 during electrodeposition.

Electrodeposition system 1300 further comprises a computing system 1340. Aspects of computing system 1340 are described in more detail below with regard to FIG. 30. Computing system 1340 may comprise instructions 1342 executable to control any suitable functions of electrodeposition system 1300. Example functions include electrodeposition processes and substrate loading/unloading processes. In some examples, computing system 1340 may be configured to communicate with a remote computing system 1344 using a suitable computer network. Remote computing system 1344 may comprise any suitable computing system. Examples include a networked workstation computer, an enterprise computing system, and/or a cloud computing system. It will be understood that remote computing system 1344 may be in communication with and control a plurality of electrodeposition systems in some examples.

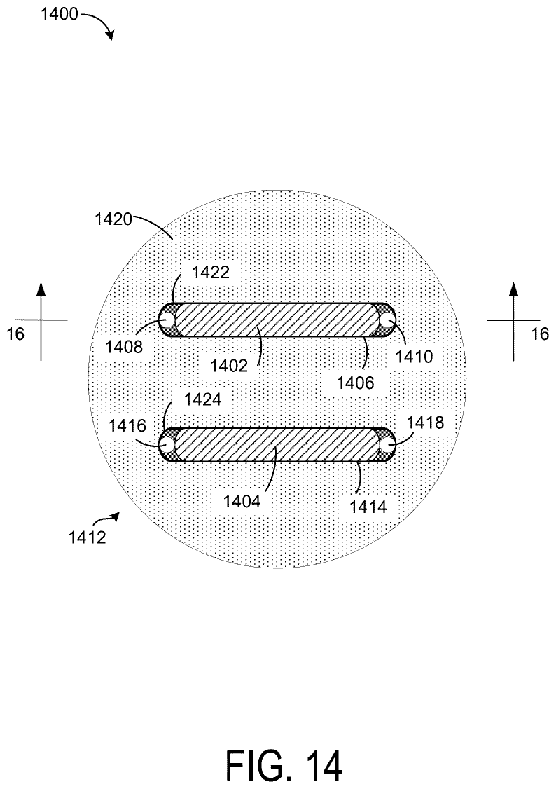

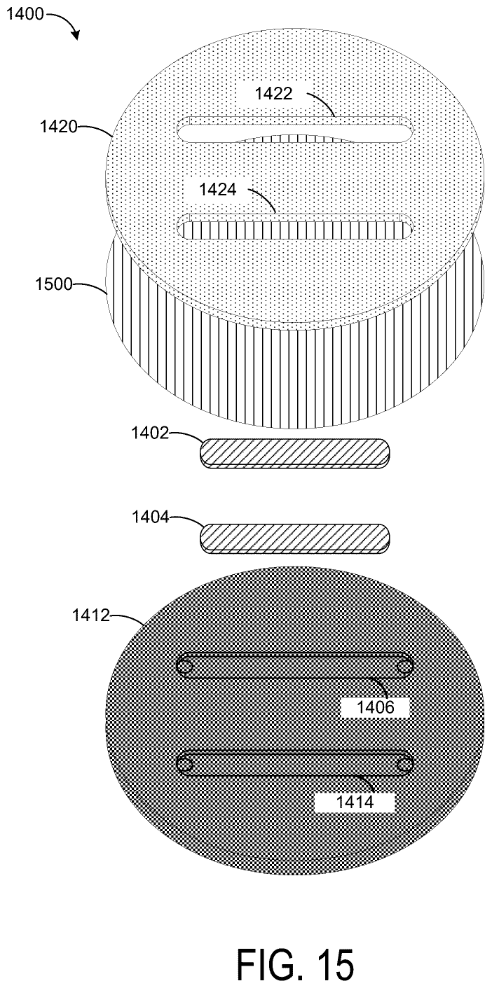

As mentioned above, anolyte flow channels can be used to generate sufficient linear anolyte flow velocity to prevent bubbles from accumulating beneath an ion exchange membrane. FIG. 14 schematically illustrates a top view of an example inert anode assembly 1400. FIG. 15 illustrates an exploded view of inert anode assembly 1400. Inert anode assembly 1400 is an example of inert anode assembly 1308. Inert anode assembly 1400 comprises a first inert anode 1402 and a second inert anode 1404. First inert anode 1402 is electrically coupled to an anodic potential. In some examples, first inert anode 1402 can be electrically connected to the anodic potential using metals screws that secure first inert anode 1402. In other examples, first inert anode 1402 can electrically connect to an electrical pad adjacent to first inert anode 1402. Similarly, second inert anode 1404 is electrically coupled to the anodic potential. In some examples, first and second inert anodes 1402, 1404 are connected to the same anodic potential. In other examples, first and second inert anodes 1402, 1404 are connected to different anodic potentials.

Inert anode assembly 1400 further comprises a first anolyte flow channel 1406. First anolyte flow channel 1406 defines a first segmented area of anolyte flow across first inert anode 1402. The first segmented area of anolyte flow enters first anolyte flow channel 1406 at a first inlet 1408 and exits through a first outlet 1410. First anolyte flow channel 1406 is at least partially defined by an anolyte channel component 1412, as shown in FIG. 15. Similarly, a second anolyte flow channel 1414 defines a second segmented area of anolyte flow across second inert anode 1404. Anolyte enters second anolyte flow channel 1414 at a second inlet 1416 and exits through a second outlet 1418. In some examples, the anolyte in the first anolyte flow channel 1406 may flow in an opposite direction of the anolyte in the second anolyte flow channel 1414. In other examples, the anolyte in the first anolyte flow channel 1406 and the anolyte in the second anolyte flow channel 1414 may flow in a same direction.

Inert anode assembly 1400 further comprises a cathode chamber bottom component 1420. Cathode chamber bottom component 1420 is configured to define a bottom portion of a cathode chamber in an electrodeposition cell of an electrodeposition system. Cathode chamber bottom component 1420 comprises a first opening 1422 and a second opening 1424. First opening 1422 permits ionic current to flow between a catholyte in first opening 1422 and an anolyte in first anolyte flow channel 1406. Similarly, second opening 1424 permits ionic current to flow between a catholyte in second opening 1424 and an anolyte in second anolyte flow channel 1414.

Inert anode assembly further comprises an ion exchange membrane 1500 (not shown in FIG. 14 for clarity). Ion exchange membrane 1500 is positioned between cathode chamber bottom component 1420 and anolyte channel component 1412. Positioning the ion exchange membrane 1500 between cathode chamber bottom component 1420 and anolyte channel component 1412 reduces an area of ion exchange membrane 1500 that is exposed to catholyte and anolyte compared to electrodeposition systems that omit anolyte flow channels as disclosed. This may help to reduce deformations of ion exchange membrane 1500 that can trap gas bubbles.

In some examples, ion exchange membrane 1500 comprises a cation exchange membrane. In such examples, cations generated at first inert anode 1402 and second inert anode 1404 flow through ion exchange membrane 1500 into a catholyte in first opening 1422 and second opening 1424 of cathode chamber bottom component 1420. For example, in some example processes, water is oxidized at first inert anode 1402 and second inert anode 1404. In such examples, protons flow through ion exchange membrane 1400. In such an example, metal ions for deposition may be added to the catholyte or the anolyte for replenishment.

In other examples, ion exchange membrane 1500 comprises an anion exchange membrane. In such examples, anions in the catholyte flow through ion exchange membrane 1400 toward first anolyte flow channel 1406 and second anolyte flow channel 1414 during an electrodeposition process. As a more specific example, where the catholyte comprises copper sulfate for depositing copper films, sulfate anions may travel through ion exchange membrane 1500. In such examples, metal ions for electrodeposition may be added to the catholyte for replenishment.

In the depicted example, inert anode assembly 1400 comprises two parallel anolyte flow channels. First anolyte flow channel 1406 and second anolyte flow channel 1414 may be fluidically connected in parallel or in series. In other examples, an inert anode assembly may comprise any other suitable number of and arrangement of anolyte flow channels. A number and configuration of anolyte flow channels may be selected based on various factors. For example, a number and configuration of anolyte flow channels may be selected to achieve a desired ionic current uniformity between an inert anode and a cathode. A number and configuration of anolyte flow channels alternatively or additionally may be based upon a desired linear flow velocity through the anolyte flow channels in view of a pumping system used to circulate anolyte. In addition to linear anolyte flow channels, other example configurations include anolyte flow channels arranged as concentric shapes.

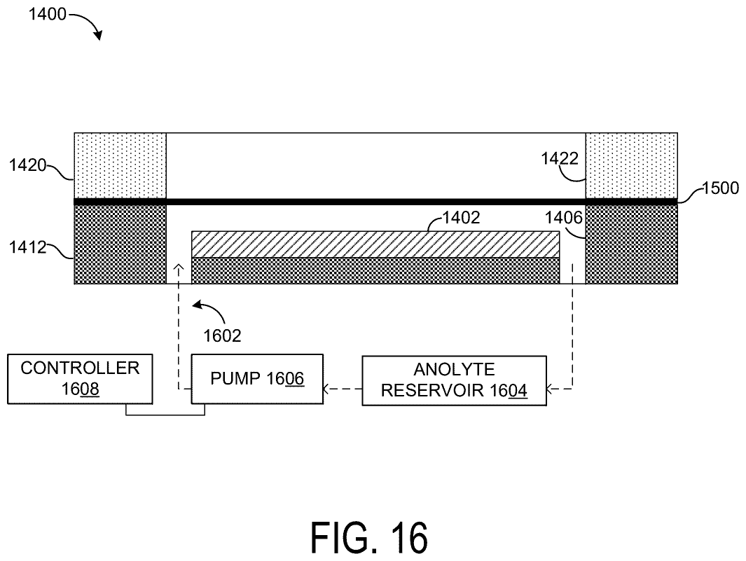

FIG. 16 schematically shows a sectional side view of inert anode assembly 1400 taken along line 16-16 of FIG. 14. As shown, ion exchange membrane 1500 is positioned between cathode chamber bottom component 1420 and anolyte channel component 1412. As shown, first anolyte flow channel 1406 directs anolyte flow across first inert anode 1402, as indicated at 1602. First anolyte flow channel 1406 is configured to generate a sufficient linear flow velocity to prevent gas bubbles from accumulating beneath ion exchange membrane 1500. In some examples, first anolyte flow channel 1406 may be configured to generate a linear flow velocity within a range of 0.1 to 10 meters per second. The anolyte flow enters a circulating loop from first anolyte flow channel 1406 to an anolyte reservoir 1604 and a pump 1606. The gas bubbles may be vented from the anolyte in anolyte reservoir 1604, or from any other suitable location along the circulating loop. Controller 1608 controls a flow rate generated by pump 1606. The flow rate may be selected to generate a desired linear flow velocity through first anolyte flow channel 1606. Second anolyte flow channel 1414, which is not shown in FIG. 16, functions in a same manner as first anolyte flow channel 1406.

The depicted inert anode assembly 1400 may be more compact than a conventional anode chamber used in an electrodeposition tool. This is at least because first anolyte flow channel 1406 and second anolyte flow channel 1414 may occupy less space than other anode chambers. Further, an anolyte volume may be reduced using inert anode assembly 1400 compared to the conventional anode chamber. This is again due at least to the smaller volume of first anolyte flow channel 1406 and second anolyte flow channel 1414.

Anolyte channel component 1412 and cathode chamber bottom component 1420 may be clamped or otherwise held together when installed in an electroplating tool. In some examples, a plurality of fasteners, such as screws, may be used to fasten together anolyte channel component 1412 and cathode chamber bottom component 1420. In other examples, anolyte channel component 1412 and cathode chamber bottom component 1420 may be coupled together in any other suitable manner. One or more sealing components may be used to prevent leakage of the anolyte. Examples include one or more O-rings arranged between anolyte channel component 1412 and cathode chamber bottom component 1420.

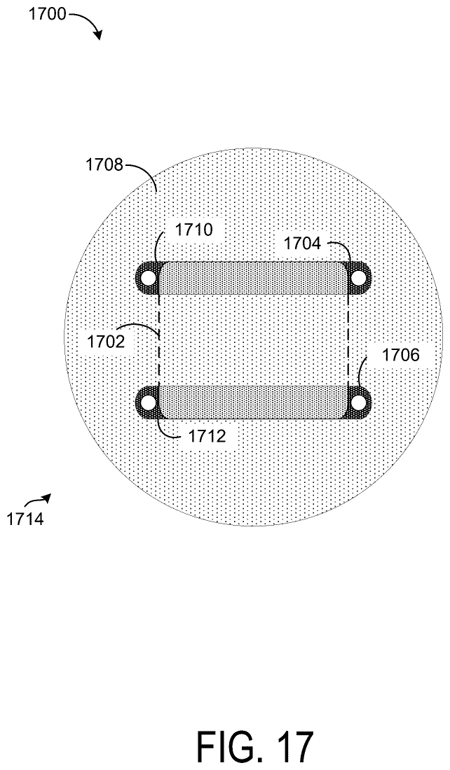

In the example of FIGS. 14-16, each anolyte flow channel is associated with a corresponding inert anode. In other examples, an inert anode may comprise a shared inert anode that is shared between two or more anolyte flow channels. FIG. 17 schematically shows an example inert anode assembly 1700 having a shared inert anode 1702. Inert anode assembly 1700 is an example of inert anode assembly 1308. A first anolyte flow channel 1704 defines a first segmented area of anolyte flow across shared inert anode 1702. Further, a second anolyte flow channel 1706 defines a second segmented area of anolyte flow across shared inert anode 1702.

Inert anode assembly 1700 further comprises a cathode chamber bottom component 1708 with a first opening 1710 and a second opening 1712. First opening 1710 is positioned opposite first anolyte flow channel 1704. First opening 1710 allows ionic current to flow between a catholyte in first opening 1710 and an anolyte in first anolyte flow channel 1704 during an electrodeposition process. Similarly, a second opening 1712 is positioned opposite second anolyte flow channel 1706. Inert anode assembly 1700 further comprises an ion exchange membrane (not shown) positioned between cathode chamber bottom component 1708 and an anolyte channel component 1714. In other examples, inert anode assembly 1700 can comprise any other suitable number of and/or configuration of anolyte flow channels and/or openings in cathode chamber bottom component 1708.

As previously mentioned, an anolyte flow channel can be configured to generate a sufficient linear flow velocity to prevent bubbles from accumulating beneath an ion exchange membrane. In the above-described examples, the disclosed inert anode assemblies comprise plural analyte flow channels. In other examples, an anolyte flow channel may have a directional change along a length of the channel to cover a wider area, as opposed to the plural anolyte flow channels. In all of these examples, a width of the anolyte flow channel is smaller than the length of the anolyte flow channel to achieve the linear flow velocity across the width of the anolyte flow channel.

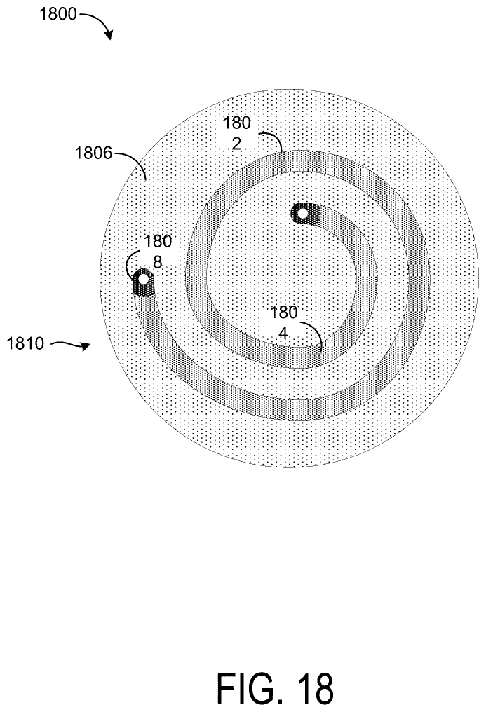

FIG. 18 schematically shows an example inert anode assembly 1800 comprising an anolyte flow channel 1802 having a spiral path. Inert anode assembly 1800 is an example of inert anode assembly 1308. Anolyte flow channel 1802 defines an area of anolyte flow across an inert anode 1804. As shown, anolyte flow channel 1802 comprises a width that is smaller than a length of anolyte flow channel 1802.

Inert anode assembly 1800 further comprises a cathode chamber bottom component 1806 with an opening 1808. Opening 1808 is positioned opposite anolyte flow channel 1802. In the depicted example, opening 1808 comprises the same spiral path as anolyte flow channel 1802. In other examples, opening 1808 can comprise a different configuration than anolyte flow channel 1802. Opening 1808 allows ionic current to flow between a catholyte in opening 1808 and an anolyte in anolyte flow channel 1802 during an electrodeposition process. Inert anode assembly 1800 further comprises an ion exchange membrane (not shown) positioned between cathode chamber bottom component 1806 and an anolyte channel component 1810.

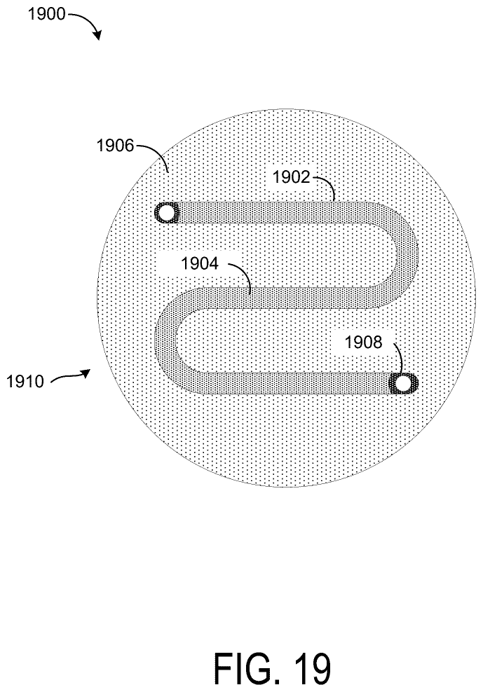

FIG. 19 shows another example inert anode assembly 1900 comprising an anolyte flow channel 1902 having a directional change. In this example, anolyte flow channel 1902 comprises a serpentine path. Inert anode assembly 1900 is an example of inert anode assembly 1308. Anolyte flow channel 1902 defines an area of anolyte flow across an inert anode 1904. As shown, anolyte flow channel 1902 comprises a length and a width, where the width is smaller than the length.

Inert anode assembly 1900 further comprises a cathode chamber bottom component 1906 with an opening 1908. Opening 1908 is positioned opposite anolyte flow channel 1902. In the depicted example, opening 1908 comprises the same serpentine path as anolyte flow channel 1902. In other examples, opening 1908 can comprise a different configuration than anolyte flow channel 1902. Opening 1908 allows ionic current to flow between a catholyte in opening 1908 and an anolyte in anolyte flow channel 1902 during an electrodeposition process. Inert anode assembly 1900 further comprises an ion exchange membrane (not shown) positioned between cathode chamber bottom component 1906 and an anolyte channel component 1910.

As ions flow between an anolyte flow channel and a cathode chamber, concentrations of ions can change in the anolyte and/or the catholyte. For example, where an ion exchange membrane comprises a cation exchange membrane, protons migrate from the anolyte to the catholyte. This can increase an acidity of the catholyte over time, and may require periodic intervention to maintain a desired ph. Thus, to help reduce a flow of protons to the cathode chamber, an electrodeposition system may use an intermediate channel component defining one or more intermediate flow channels through which an intermediate electrolyte flows. In some examples, the one or more intermediate flow channels may be separated from an anolyte flow channel by an anion exchange membrane, and from a cathode chamber by a cation exchange membrane. The intermediate electrolyte can include a metal salt comprising metal ions to be electrodeposited. As protons are generated in the anolyte at an inert anode, the anions in the intermediate solution can traverse the anion exchange membrane to migrate into an anolyte flow channel in which the inert anode is located to balance charge. Likewise, metal ions can traverse the cation exchange membrane to migrate into the cathode chamber for electrochemical reduction. In this manner, a pH within the cathode chamber can be more easily maintained. One example of a metal salt that may be included in the intermediate electrolyte is copper sulfate.

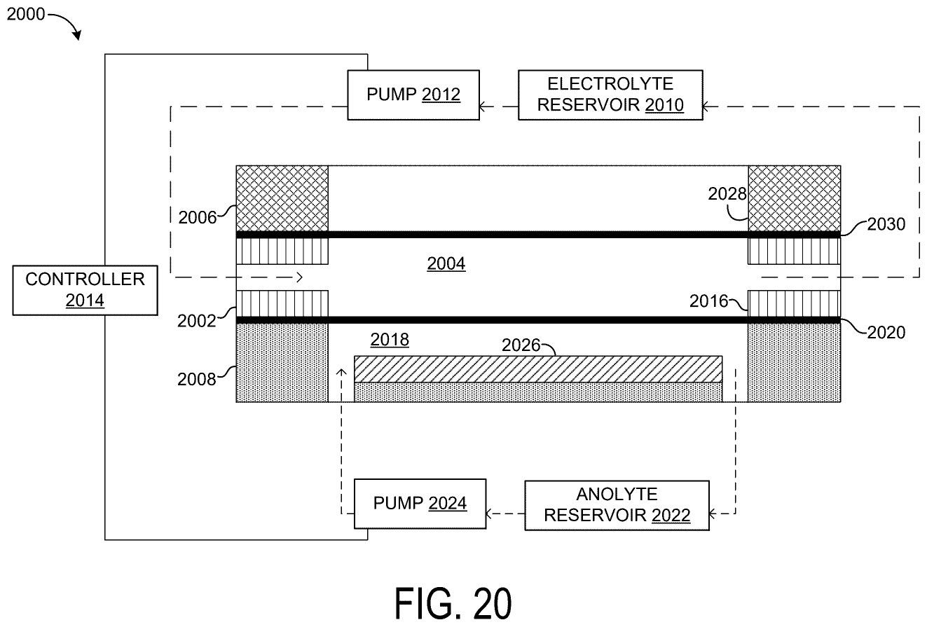

FIG. 20 schematically shows an example inert anode assembly 2000 comprising an intermediate channel component 2002. Inert anode assembly 2000 is an example of inert anode assembly 1308. Intermediate channel component 2002 at least partially defines an intermediate flow channel 2004. As described above, intermediate flow channel 2004 is configured to hold a flow of an intermediate electrolyte. The intermediate electrolyte may comprise a metal salt to provide metal ions to a catholyte and anions to an anolyte.

Intermediate channel component 2002 is positioned between a cathode chamber bottom component 2006 and an anolyte channel component 2008. The intermediate electrolyte flows in a circulating loop through intermediate flow channel 2004, an electrolyte reservoir 2010, and a pump 2012. The immediate electrolyte may be replenished in electrolyte reservoir 2010. A controller 2014 controls a flow rate generated by pump 2012. Thus, controller 2014 can control a linear flow velocity of the intermediate electrolyte through intermediate flow channel 2004.

An opening 2016 of intermediate flow channel 2004 is positioned opposite of an anolyte flow channel 2018. As such, opening 2016 allows anions from the intermediate electrolyte in intermediate flow channel 2004 to traverse an anion exchange membrane 2020 and migrate to an anolyte in anolyte flow channel 2018.

The anolyte flow enters a circulating loop from anolyte flow channel 2018 to an anolyte reservoir 2022 and a pump 2024. Controller 2014 controls pump 2024 and thus, a linear flow velocity across inert anode 2026. The anolyte flow channel 2018 may be configured to create a sufficient linear flow velocity to prevent bubble accumulation beneath anion exchange membrane 2020. In addition, intermediate channel component 2002 prevents bubbles from migrating to cation exchange membrane 2030 between intermediate channel component 2002 and cathode chamber bottom component 2006. This further may help to prevent bubbles from impacting plating uniformity.

Opening 2016 of intermediate flow channel 2004 also is positioned opposite an opening 2028 of cathode chamber bottom component 2006. Such a configuration allows cations from the intermediate electrolyte in intermediate flow channel 2004 to traverse a cation exchange membrane 2030 to migrate to a catholyte in opening 2028 of cathode chamber bottom component 2006 during an electrodeposition process.

While intermediate channel component 2002 is shown with a single intermediate flow channel, inert anode assembly 2000 may comprise any other suitable number of intermediate flow channels between an anolyte flow channel and an opening of a cathode chamber. Further, inert anode assembly 2000 may comprise any suitable number of additional intermediate channel components and associated ion exchange membranes.

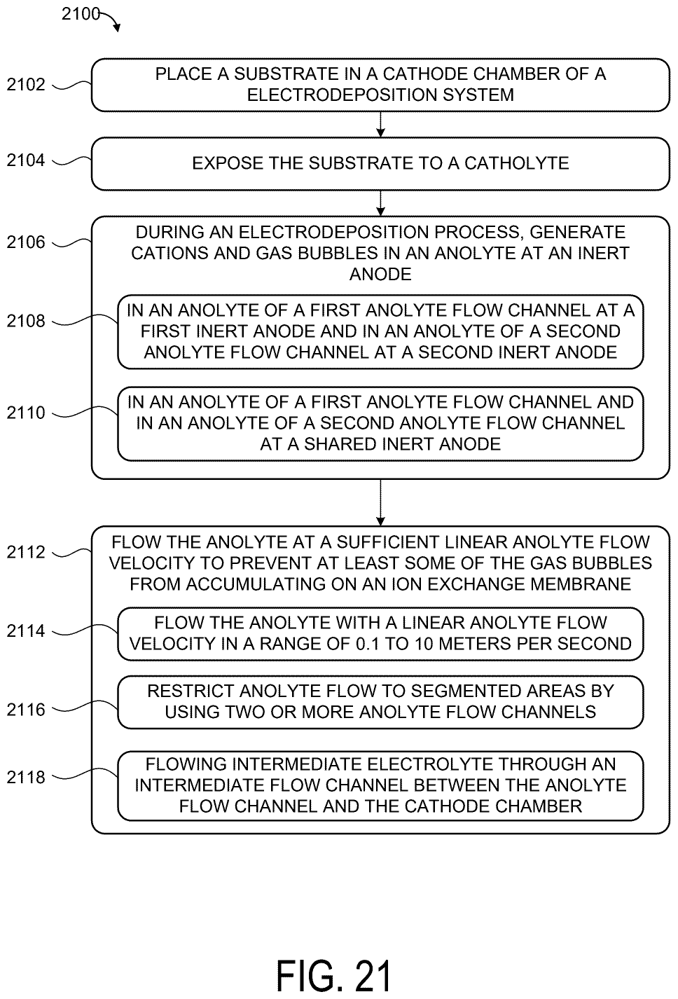

As previously mentioned, an inert anode assembly according to the present disclosure may help to reduce bubble accumulation on an ion exchange membrane in an electrodeposition system. FIG. 21 illustrates a flow diagram of an example method 2100 for operating an electrodeposition system. Method 2100 may be performed on any suitable electrodeposition system comprising an inert anode assembly. Examples include electrodeposition system 1300 and inert anode assemblies 1400, 1700, 1800, 1900, and 2000.

Method 2100 comprises, at 2102, placing a substrate in a cathode chamber of the electrodeposition system. Method 2100 further comprises, at 2104, exposing the substrate to a catholyte in the cathode chamber. The catholyte includes metal ions for electrodeposition on the substrate. Continuing, method 2100 comprises, at 2106, during an electrodeposition process, generating cations and gas bubbles in an anolyte at an inert anode of the inert anode assembly. In some examples, the anolyte may comprise an aqueous solution. As such, the cations may comprise hydrogen cations and the gas bubbles may comprise molecular oxygen generated by oxidation of water molecules. The cations and the gas bubbles may be generated in a first anolyte flow channel at a first inert anode and in a second anolyte flow channel at a second inert anode, as indicated at 2108. Alternatively or additionally, the cations and the gas bubbles may be generated at a shared inert anode that is shared between anolyte flow channels, as indicated at 2110.

Continuing, method 2100 comprises, at 2112, flowing the anolyte at a sufficient linear flow velocity to prevent at least some gas bubbles from accumulating on an ion exchange membrane between an anolyte flow channel and the catholyte. Such a configuration may help to carry away the bubbles while in suspension. In such a manner, the gas bubbles may not agglomerate into larger bubbles that interfere with electrodeposition. Further, the linear flow velocity across the inert anode may help to increase a mass transfer in the catholyte. In some examples, flowing the anolyte at the sufficient linear flow velocity comprises flowing the anolyte with a linear flow velocity in a range of 0.1 to 10 meters per second, as indicated at 2114. In some examples, method 2100 comprises, at 2116, restricting anolyte flow to segmented areas by using two or more anolyte flow channels formed in an anolyte channel component of the inert anode assembly. Such a configuration may help to reduce a volume of the anolyte used in the electrodeposition system compared to a conventional anode chamber.

As mentioned above, some inert anode assemblies comprise an intermediate flow channel through which an intermediate electrolyte flows. The intermediate flow channel may be separated from the anolyte flow channel by an anion exchange membrane. The intermediate flow channel further may be separated from the cathode chamber by a cation exchange membrane. As such, in some examples, method 2100 comprises, at 2118, flowing an intermediate electrolyte through an intermediate flow channel between the anolyte flow channel and the cathode chamber. The use of the intermediate flow channel helps to maintain a desired pH of the catholyte during electrodeposition, as described above.

Thus, the use of an inert anode assembly as described herein may help to reduce or prevent gas bubble accumulation on an ion exchange membrane in an electrodeposition system. The reduction of the gas bubble accumulation may help to prevent the electrodeposition non-uniformities. Further, an anolyte volume may be reduced using the disclosed inert anode assembly due to at least a smaller volume of anolyte flow channels of the inert anode assembly compared to other anode chambers.

Current bubble mitigation often relies on a pitch and material “slickness” of an ion exchange membrane to bubble movement, combined with increased local fluid flow, to direct bubbles away from a substrate surface. Regardless of how effective these variables are, bubbles can still build up under the membrane and beneath the substrate. Accordingly, examples also are disclosed that relate to managing bubbles generated at an inert anode during the electrodeposition process. In one example, an anode chamber comprises a bubble diverter. The bubble diverter acts as a physical barrier to direct a flow of bubbles generated at an inert anode to a stilling structure at which the bubbles are vented to atmosphere. Ions can pass beneath or through openings in the bubble diverter. Thus, an ionic current between the inert anode and the substrate is not interrupted by the bubble diverter.

In some examples, one or more inert anodes are positioned around an internal periphery of the anode chamber, outside the target area for electrodeposition. The bubble diverter partially segregates the ion exchange membrane and substrate from the inert anodes, so that bubbles do not impact electrodeposition performance. The stilling structure can be located in an anolyte circulation loop. Anolyte and gas bubbles can thus flow through the stilling structure, removing the bubbles from the anolyte. A contactor can be employed to remove any residual gas in the anolyte. The anolyte that returns to the anode chamber can thus be effectively degassed. Further, in some examples, the bubble diverter comprises a plurality of apertures which allow for ionic current to pass through. An ionic current can be adjusted by altering the size of the apertures.

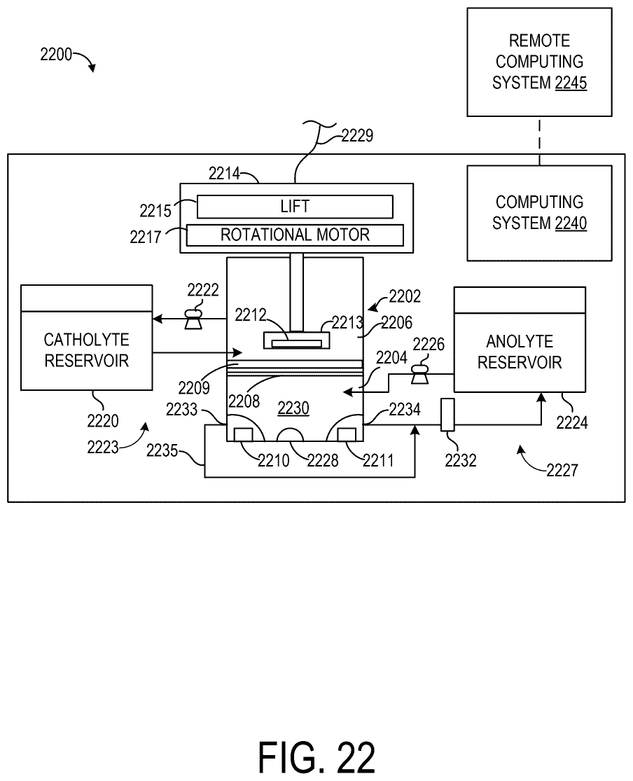

Prior to discussing these examples in more detail, FIG. 22 schematically shows a block diagram of another example electroplating tool 2200. Electroplating tool 2200 comprises an electroplating cell 2202 comprising an anode chamber 2204 and a cathode chamber 2206. Electroplating tool 2200 further comprises an ion exchange membrane 2208 separating the anode chamber 2204 and the cathode chamber 2206, and a high-resistance virtual anode (HRVA) 2209 within cathode chamber 2206. HRVA 2209 comprises an ionically resistive element that approximates a suitably constant and uniform current source in proximity to a substrate cathode.

Anode chamber 2204 comprises inert anodes 2210 and 2211. Anode chamber 2204 further comprises an anolyte. Cathode chamber 2206 comprises a catholyte. The catholyte comprises an ionic species to be deposited on a cathode layer of a substrate 2212 as a metal by electrochemical reduction. The anolyte comprises a conductive electrolyte solution that is a different composition than the catholyte. Bulk anolyte and/or catholyte solutions can be added at times to replenish the ionic species.

Ion exchange membrane 2208 prevents organic species and anionic species from crossing between cathode chamber 2206 and anode chamber 2204, while allowing cations to cross from anode chamber 2204 to cathode chamber 2206.

Substrate holder 2213 is coupled to a substrate holder movement system 2214 comprising a lift 2215 that is configured to adjust a spacing between substrate holder 2213 and HRVA 2209. For example, lift 2215 can lower substrate holder 2213 to position substrate 2212 within the catholyte for electroplating. Lift 2215 further can raise substrate holder 2213 from the catholyte after electroplating. Substrate holder movement system 2214 further can comprise components to control the opening and closing of substrate holder 2213.

The catholyte can be circulated between cathode chamber 2206 and a catholyte reservoir 2220 via a combination of gravity and one or more pumps 2222 within a catholyte circulation loop 2223. Likewise, the anolyte can be circulated through anolyte reservoir 2224 and anode chamber 2204 via a combination of gravity and one or more pumps 2226 within an anolyte circulation loop 2227.

In some electroplating tools, plating operations can be performed in parallel on multiple substrates using multiple plating cells. In some such examples, central catholyte and/or anolyte reservoirs can supply multiple plating cells with catholyte and/or anolyte. In other such examples, separate catholyte and/or anolyte reservoirs can be used to supply multiple plating cells. In yet other examples, an electroplating tool can comprise a single plating cell. Where an electroplating tool comprises multiple plating cells, a single lift can be configured to lift two or more substrate holders for two or more different plating cells.

Substrate holder 2213 is lowered by lift 2215 toward HRVA 2209 after substrate 2212 is loaded into substrate holder 2213. In some examples, substrate holder 2213 can be rotated by a rotational motor 2217 during electroplating. Substrate 2212 faces a surface of the HRVA 2209, and is spaced from HRVA 2209 by a plating gap during electroplating. An electric field is established between anodes 2210 and 2211 and substrate 2212. This electric field drives dissolved metal cations from anode chamber 2204 into cathode chamber 2206. At the substrate 2212, the metal cations are electrochemically reduced to deposit on substrate 2212. An anodic potential is applied to anodes 2210 and 22122 via charge plate 2228 and a cathodic potential is provided to the cathode of substrate 2212 via a cathode electrical connection 2229 to form a circuit. In some examples, anodes 2210 and 2211 are connected to the same anodic potential. In other examples, anodes 2210 and 2211 are connected to different anodic potentials.

As described, anodes 2210 and 2211 are inert anodes. As such, protons and oxygen gas bubbles can be formed by electrolysis of water when an anodic potential is applied to anodes 2210 and 2211. To prevent oxygen gas bubbles from moving to ion exchange membrane 2208 and interfering with ionic current directed to substrate 2212, anodes 2210 and 2211 are positioned towards the periphery of anode chamber 2204. Further, a bubble diverter 2230 is positioned within anode chamber 2204 laterally between anodes 2210 and 2211 and ion exchange membrane 2208. Bubble diverter 2230 is configured to direct a flow of bubbles generated at anodes 2210 and 2211 to a stilling structure 2232 at which the bubbles are vented to atmosphere.

In this example, stilling structure 2232 is located within anolyte circulation loop 2227. Bubble diverter 2230 directs bubbles generated at anode 2210 to stilling port 2233, and directs bubbles generated at anode 2211 to stilling port 2234. Stilling ports 2233 and 2234 direct bubbles into anolyte circulation loop 2227 upstream of stilling structure 2232. In this examples, an additional stilling conduit 2235 is used to connect stilling port 2233 to anolyte circulation loop 2227.

Electroplating tool 2200 further comprises a computing system 2240, aspects of which are described in more detail below with regard to FIG. 30. Computing system 2240 comprises instructions executable to control functions of electroplating tool 2200. In some examples, computing system 2240 can be configured to communicate with a remote computing system 2245 via a suitable computer network. Remote computing system 2245 may comprise any suitable computing system. Examples include a networked workstation computer, an enterprise computing system, and/or a cloud computing system. Remote computing system 2245 can be in communication with and control a plurality of electroplating tools in some examples.

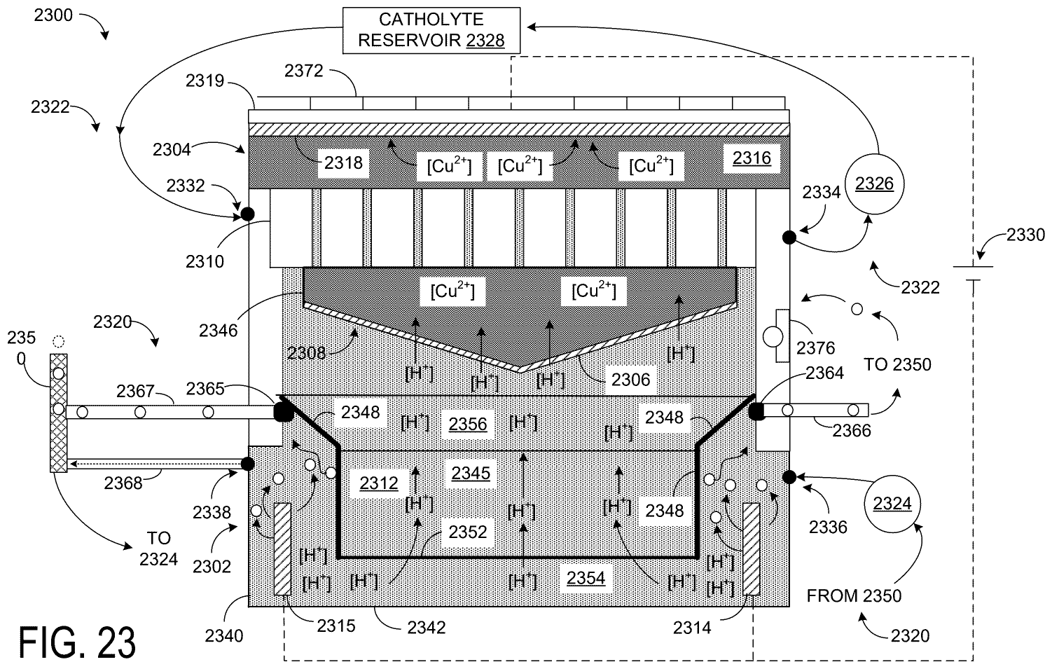

FIG. 23 schematically shows an example electrodeposition system 2300 comprising an inert anode, and illustrates proton ([H+]) and oxygen bubble (O) formation. Electrodeposition system 2300 comprises an anode chamber 2302 and a cathode chamber 2304. Electrodeposition system 2300 further comprises an ion exchange membrane 2306 separating anode chamber 2302 and cathode chamber 2304. Ion exchange membrane 2306 is supported by membrane frame 2308. Electrodeposition system 2300 further comprises a HRVA 2310 disposed within cathode chamber 2304.

As described above with regard to FIG. 3, anode chamber 2302 comprises an anolyte bath 2312 in which inert anodes 2314 and 2315 are disposed. Cathode chamber 2304 comprises a catholyte bath 2316 that comprises ionic copper (Cu²⁺) to be deposited onto a substrate 2318 that acts as a cathode. Although primarily described with regard to copper deposition, other metal ion chemistry, such as, but not limited, to Au, Ag, Ni, Al, In, or Co, or metal alloy chemistry, such as, but not limited to Ni/P, Ni/Co, Ni/Zn, Au/Cu, or Sn/Ag can be used without departing from the scope of this disclosure. Substrate 2318 is held within a substrate holder 2319 during deposition.

Anolyte bath 2312 is located within an anolyte circulation loop 2320 that includes a pump 2324 and an anolyte reservoir (not shown). Catholyte bath 2316 is located within a catholyte circulation loop 2322 that includes a pump 2326 and a catholyte reservoir 2328. A voltage source 2330 applies a voltage across substrate 2318 and inert anode 2314 to drive flow of copper ions for deposition on substrate 2318.

Catholyte enters cathode chamber 2304 at inlet 2332 and exits at outlet 2334. In scenarios wherein anolyte bath 2312 comprises Cu²⁺ ions, ion exchange membrane 2306 is a cation exchange membrane that passes Cu²⁺ ions from anolyte bath 2312 to catholyte bath 2316. Any Cu²⁺ ions crossing ion exchange membrane 2306 replace at least some copper ions in catholyte bath 2316 that are reduced onto substrate 2318. Cu²⁺ ions can also be replenished from catholyte reservoir 2328, regardless of the composition of anolyte bath 2312. As shown, ion exchange membrane 2306 can be a cation exchange membrane to allow for the passage of protons from anolyte bath 2312 to catholyte bath 2316. This ionic current results in Cu²⁺ ions being deposited on substrate 2318.

Anolyte enters anode chamber 2302 at inlet 2336 and exits at outlet 2338. However, more inlets and outlets may be present, and inlets and/or outlets may be additionally or alternatively positioned on anode chamber base 2342 or in any suitable position.

As described above, for inert anodes 2314 and 2315, the oxidation and reduction reactions for copper electrodeposition comprise:

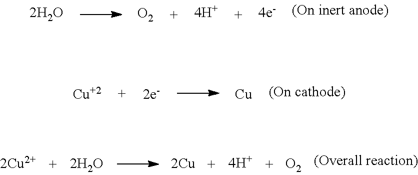

Similar reactions may occur for other metal species. As such, unlike for an active anode, inert anodes 2314 and 2315 do not produce metal cations in anolyte bath 2312. Instead, circulating anolyte flows across inert anodes 2314 and 2315, where water molecules are oxidized to form molecular oxygen and hydrogen ions. For 1 mole of copper plated at the cathode, 0.5 mole of molecular oxygen and 2 moles of protons (H⁺) are generated at the inert anode. As described above, uniform plating at substrate 2318 is dependent on mitigating bubble accumulation at ion exchange membrane 2306 without disrupting ionic current between inert anodes 2314 and 2315 and substrate 2318.

Bubbles produced at inert anodes float upwards. In traditional electrodeposition systems, where the inert anode is positioned beneath the substrate at or near the center of the anode chamber, the bubbles will float up to the membrane frame. With a membrane frame that slopes upwards towards the periphery of the anode chamber, the bubbles can drift towards the upper corners of the membrane frame, where vents can be positioned to remove the bubbles from the anolyte. However, if the membrane has any sag between membrane frame struts, bubbles can get caught in the sags.

As such, electrodeposition system 2300 is designed to bias the flow of bubbles so they do not impinge on membrane frame 2308 or ion exchange membrane 2306. In this example, inert anodes 2314 and 2315 are located towards a periphery of anode chamber 2302 (e.g., closer to anode chamber outer wall 2340 than to a center of anode chamber 2302). In this way, bubbles floating directly upwards from inert anodes 2314 and 2315 are less likely to impinge on ion exchange membrane 2306 than they would for an inert anode centrally positioned beneath substrate 2318.

To further reduce bubble trafficking towards ion exchange membrane 2306, a bubble diverter 2345 is mounted in anode chamber 2302. As shown in FIG. 23, bubble diverter 2345 is positioned such that bubbles floating directly upward from the inert anodes 2314 and 2315 will travel on an opposite side of an outer wall 2348 of bubble diverter 2345 as ion exchange membrane 2306. Bubble diverter 2345 is positioned between membrane frame 2308 and anode chamber base 2342. A membrane interface seal 2346 (e.g., an O-ring) is positioned between membrane frame 2308 and bubble diverter 2345. Membrane interface seal 2346 prevents bubbles from crossing outer wall 2348 at the interface between bubble diverter 2345 and membrane frame 2308. Membrane frame 2308 can be fastened to bubble diverter 2345 to apply downwards pressure on bubble diverter 2345, increasing the strength of the seal between the two components. A base of bubble diverter 2345 can attach, rest on, or be inserted into anode chamber base 2342.

In this example, inert anodes 2314 and 2315 are located to an exterior of bubble diverter 2345 while ion exchange membrane 2306 is located within an interior of bubble diverter 2345. Outer wall 2348 of bubble diverter 2345 partially separates a region of anode chamber 2302 adjacent to ion exchange membrane 2306 from a region of anode chamber 2302 configured to direct a flow of bubbles to anolyte circulation loop 2320. Bubble diverter 2345 can direct a flow of bubbles generated at inert anodes 2314 and 2315 toward a stilling structure 2350, at which the bubbles are vented to atmosphere. Stilling structure 2350 can be any suitable structure that allows undissolved gases to evolve and evaporate to atmosphere. Stilling structure can be shaped as a column, or have any other suitable configuration.

In the depicted example, a bottom edge 2352 of bubble diverter 2345 is spaced from anode chamber base 2342 forming a gap 2354 that allows ionic current to flow between the inert anodes 2314 and 2315 and ion exchange membrane 2306. Gap 2354 also allows anolyte to flow beneath the bottom edge 2352 of the bubble diverter 2345. Protons generated at inert anodes 2314 and 2315 flow towards ion exchange membrane 2306, where they cross into catholyte bath 2316. The ionic current generated by the protons helps to achieve the deposition of copper ions from catholyte onto substrate 2318.

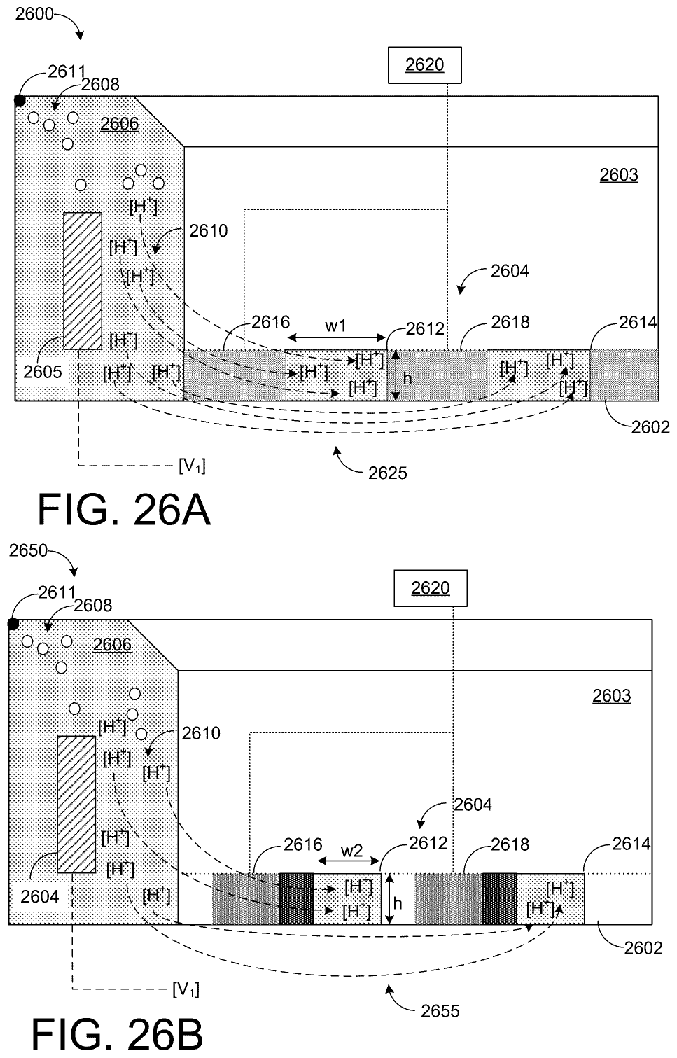

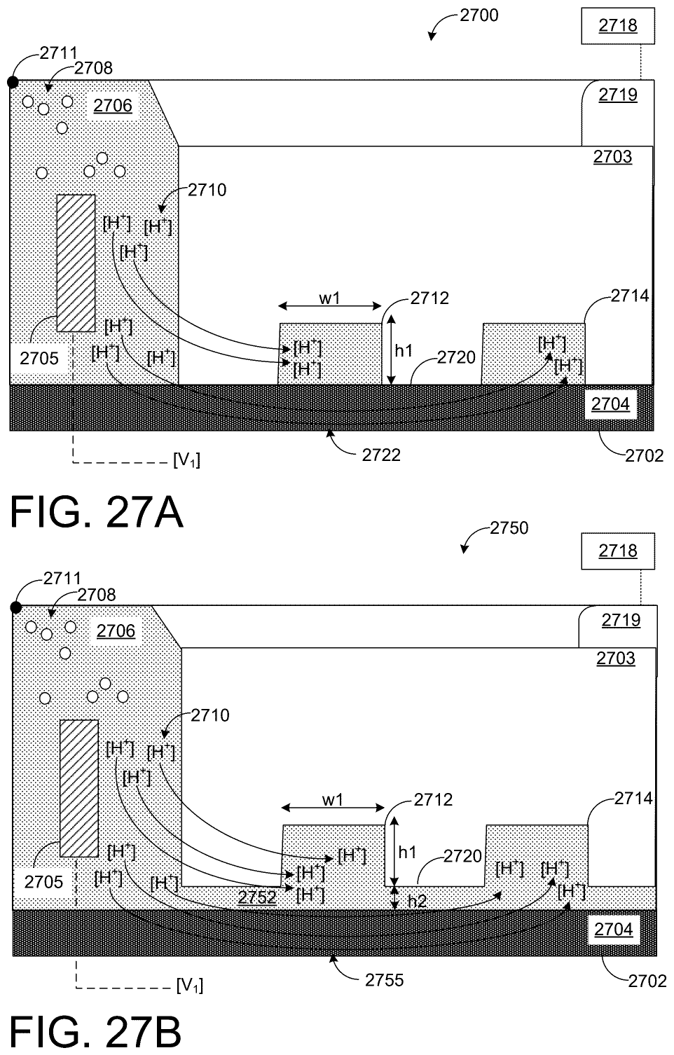

In other examples, as described in more detail below, bottom edge 2352 of bubble diverter 2345 can comprise apertures to pass ionic current and anolyte flow. In some examples, such apertures can be covered with a membrane or mesh grating to further restrict bubble trafficking to ion exchange membrane 2306. Further, as will be described further with regard to FIGS. 26A-26B and 27A-27B, in some examples the apertures comprise a variable open cross-sectional area. The size of aperture openings, the thickness of outer wall 2348, and distance from outer wall 2348 to inert anodes 2314 and 2315 can be varied to control an ionic current.

Bubble diverter 2345 is shaped to direct bubbles away from ion exchange membrane 2306 and toward stilling structure 2350. In this example, bubble diverter 2345 includes conical region 2356 that guides bubbles generate at inert anodes 2314 and 2315 towards stilling ports 2364 and 2365, respectively. In some examples, bubble diverter 2345 includes grooves or channels on an exterior surface to guide bubbles.

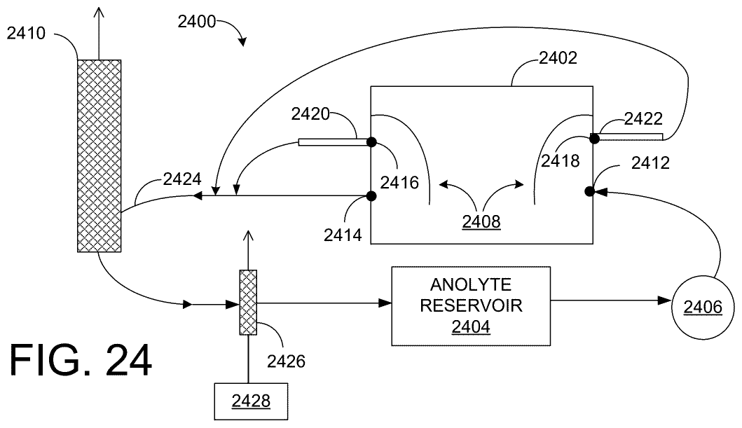

Stilling ports 2364 and 2365 are configured to direct bubbles out of anode chamber 2302 to stilling structure 2350. In this example, stilling port 2364 leads to channel 2366, and stilling port 2365 leads to channel 2367. Channel 2366 and channel 2367 are fluidically coupled to stilling structure 2350. Anolyte circulation loop 2320 also passes through stilling structure 2350 via conduit 2368. In some examples, (e.g., as described with regard to FIG. 24) channels 2366 and 2367 merge with anolyte circulation loop 2320 upstream of stilling structure 2350. Stilling ports 2364 and 2365 can be positioned in part based on fluid flow patterns from anolyte circulation loop 2320, so as to further bias bubble traffic out of anode chamber 2302. For example, stilling ports 2364 and 2365 can be positioned in areas where there is localized higher fluid velocities (e.g., at or near inlet 2336 and/or outlet 2338).

In some examples, one or more sensors can be positioned in and around electrodeposition system 2300 to monitor conditions and to provide indications of plating non-uniformity that may be indicative of bubble accumulation and/or otherwise non-uniform ionic current through ion exchange membrane 2306. For example, electrodeposition system 2300 can include a cathode current sensor array 2372 and/or an optical sensor 2376. Cathode current sensor array 2372 can monitor electrical current at different locations at substrate 2318. Optical sensor 2376 can be positioned to observe a surface of ion exchange membrane 2306 to provide visual monitoring of gas bubble accumulation. Optical sensor 2376 can comprise a photodiode, a camera, and/or any other suitable optical sensing device. Additional optical sensors, and/or other sensors, other than those shown can be positioned in and around electrodeposition system 2302.

FIG. 24 schematically shows an example anolyte circulation loop 2400. Anolyte circulation loop 2400 is an example of anolyte circulation loops 2227 and/or 2320. Anolyte circulation loop 2400 comprises an anode chamber 2402, an anolyte reservoir 2404, and a circulation pump 2406. While anolyte reservoir 2404 is shown as being upstream of circulation pump 2406, anolyte reservoir 2404 alternatively can be located downstream of circulation pump 2406.

In addition to impacting ionic current flow during electrodeposition, bubbles can also hinder flow through the anolyte circulation loop if gas accumulates in the recirculation lines. Within anode chamber 2402, bubble diverter 2408 directs the flow of bubbles to anolyte circulation loop 2400. Stilling structure 2410 is positioned upstream of circulation pump 2406. Stilling structure 2410 is exposed to atmosphere. Stilling structure 2410 can be formed from any material that is compatible with chemistries to which anode chamber 2402 is exposed. In some examples, stilling structure 2410 can be made from tetrafluoroethylene tubing.

Anode chamber 2402 comprises an anolyte inlet 2412 and an anolyte outlet 2414. Anode chamber 2402 further comprises stilling ports 2416 and 2418. Bubble diverter 2408 directs the flow of bubbles into stilling ports 2416 and 2418, though some bubbles may also exit anode chamber 2402 via anolyte outlet 2414.

Stilling port 2416 leads to a channel 2420 that connects to anolyte circulation loop 2400. Similarly, stilling port 2418 leads to channel 2422 that also connects to anolyte circulation loop 2400. As shown, all of the outlet ports and channels exiting anode chamber 2402 merge into common flow line 2424 that leads to stilling structure 2410.

Stilling structure 2410 can be tall enough to prevent overflow and wide enough to allow a majority of incoming gas bubbles to vent to atmosphere. The height of a fluid column within stilling structure 2410 is generally at least higher than the level of fluid within anode chamber 2402, and in some examples is higher than the overall level of fluid in the electrodeposition chamber.

While stilling structure 2410 can get rid of a majority of bubbles, dissolved gases can remain in the anolyte exiting stilling structure 2410. As such, anolyte circulation loop 2400 further comprises a contactor 2426 downstream of stilling structure 2410 and upstream of circulation pump 2406. Contactor 2426 is configured to remove dissolved gases from the circulating anolyte. For example, contactor 2426 can comprise a filter or membrane with an applied vacuum 2428 that separates fluid from gases. Contactor 2426 further can comprise a vent connected to a vacuum source allowing for the gases to be released to atmosphere.

Once the anolyte passes through stilling structure 2410 and contactor 2426, the anolyte returns to anode chamber 2402 sufficiently degassed. In some examples, contactor 2426 can remove both dissolved and undissolved gases. For example, contactor 2426 can be used alone, without a stilling column, during electrodeposition processes involving very low currents for a relatively long duration that do not generate excessive gas bubbles.

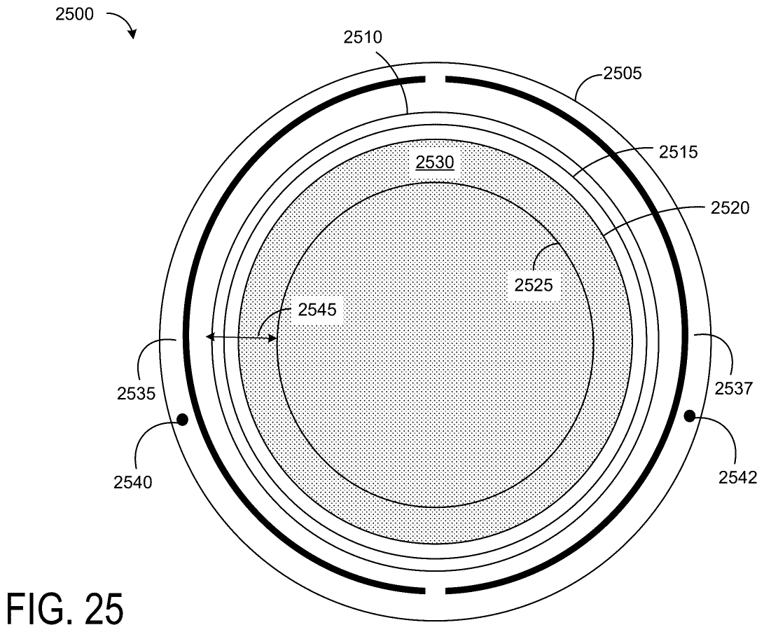

FIG. 25 schematically shows a top-down view of relative positions of some components of an example electrodeposition system 2500. Electrodeposition system 2500 is an example of electrodeposition system 2300. Depicted within electrodeposition system 2500 are positions of an outer chamber wall 2505, outer bubble diverter wall 2510, and membrane frame perimeter 2515. A substrate perimeter 2520 is also shown. Outer bubble diverter wall 2510, membrane frame perimeter 2515, and substrate perimeter 2520 are shown as having slightly different diameters, but can be closer to coincident in physical examples. Outer bubble diverter wall 2510 extends around a peripheral portion of membrane frame perimeter 2515. Outer bubble diverter wall 2510 is contiguous with lower bubble diverter wall 2525, connected by a conical region (e.g., conical region 2356 as shown in FIG. 23).

Substrate perimeter 2520 defines a substrate window 2530, indicated in FIG. 25 as a shaded region. Substrate window 2530 is a volume (in this example, cylindrically shaped) that extends from the substrate to the base of an anode chamber of electrodeposition system 2500. Substrate window 2530 can represent a target for ionic current across an ion exchange membrane, as well as a target to be maintained free of bubbles. Inert anodes 2535 and 2537 are depicted as peripheral anodes, positioned between outer chamber wall 2505 and lower bubble diverter wall 2525, and extending around a perimeter of substrate window 2530. The strength of the generated ionic current is a function of distance 2545 between inert anodes 2535 and 2535 and lower bubble diverter wall 2525. Gas bubbles are thus generated outside of substrate window 2530 at inert anodes 2535 and 2537, and directed to stilling portals 2540 and 2542. Stilling portals 2540 and 2542 are also located outside of substrate window 430.

Ionic current through the bubble diverter, in the form of protons generated at the inert anode, is based in part on the open cross-sectional area of the apertures. By adjusting the overall cross-sectional area, the ionic current density and/or flow can be adjusted accordingly. The bubble diverter apertures can be customized for specific electrodeposition processes, e.g., by machining the apertures to a desired height.

In some examples, the bubble diverter can comprise an adjustment mechanism configured to adjust an open cross-sectional area of the plurality of apertures. Such an adjustment could occur at setup, in situ, in between electrodeposition process, or during a process. The adjustment can increase the size of the apertures to increase ionic current flow, and decrease the size of the apertures to decrease ionic current flow. For example, a substrate that has been through an electrodeposition process can be evaluated using metrology. If the metrology indicates that an ionic current change is needed, the apertures can be adjusted prior to performing electrodeposition on a next substrate. For example, some wafers have higher seed resistances, and that can require more terminal effects than for wafers with lower seed resistances. Such an adjustment can allow users to fine-tune anode performance, providing flexibility versus electrodeposition systems that only provide cathode tuning capabilities.

As one example, an adjustment mechanism for altering an aperture cross sectional area of a bubble diverter can comprise a shutter system. An example shutter system is shown in FIGS. 26A-26B. At 2600, FIG. 26A shows a portion of an anode chamber 2602 comprising a bubble diverter 2603 having an actuatable shutter system 2604 in a first conformation. Anode chamber 2602 is configured with an inert anode 2605 positioned in contact with anolyte 2606. Application of voltage Vi to inert anode 2605 results in the oxidation of water to form oxygen gas bubbles, as shown at 2608, and protons, as shown at 2610. Bubble diverter directs gas bubbles to stilling port 2611.

Bubble diverter 2603 include apertures 2612 and 2614, each having a rectangular cross-sectional area with a height (h) and a width (w1). A first shutter 2616 is associated with aperture 2612 and a second shutter 2618 is associated with aperture 2614. In this example, first shutter 2616 and second shutter 2618 adjust the cross-sectional area of apertures 2612 and 2614 by varying the open width of the respective aperture. In other examples, the shutters can adjust the open height. In some examples, each shutter is individually adjustable. In other examples, the shutters are adjusted as a group. For example, first shutter 2616 and second shutter 2618 can be part of a threaded, rotatable ring of alternating apertures and solid sections, located either inside or outside of bubble diverter 2603. Movement of the rotatable ring would thus align or misalign the apertures of the ring and the apertures of bubble diverter 2603, e.g., in an iris structure. First shutter 2616 and second shutter 2618 can be adjusted manually or automatically. For example, a controller 2620 can be employed to send a signal to actuate a mechanism that adjusts positions of first shutter 2616 and second shutter 2618.

As shown at 2600, apertures 2612 and 2614 are maximally open at width w1, yielding a maximum actuatable ionic current, as shown at 2625. In FIG. 26B, at 2650, first shutter 2616 and second shutter 2618 have been actuated via controller 2620, reducing the open width of apertures 2612 and 2614 from w1 to w2. Accordingly, ionic current is reduced from a maximum actuatable ionic current, as shown at 2655. Notably, generating this change in ionic current does not require an adjustment in applied voltage V₁.

Another system for adjusting ionic current through a bubble diverter is shown in FIGS. 27A-27B. At 2700, FIG. 27A shows a portion of an anode chamber 2702 comprising a bubble diverter 2703 movable relative to a base 2704 of anode chamber 2702 in a first conformation. Anode chamber 2702 is configured with an inert anode 2705 positioned in contact with anolyte 2706. Application of voltage V₁ to inert anode 2705 results in the oxidation of water to form oxygen gas bubbles, as shown at 2708, and protons, as shown at 2710. Bubble diverter directs gas bubbles to stilling port 2711. Bubble diverter 2703 include apertures 2712 and 2714 located along a lower end of bubble diverter 2703, each having a rectangular cross-sectional area with a height (h) and a width (w1). A controller can be employed to actuate an adjustment mechanism 2719. Adjustment mechanism 2719 can be a motor or pneumatic device, for example, and can be operable as a mechanism for adjusting a position of the bubble diverter relative to a base of the anode chamber. As shown at 2700, bottom edge 2720 of bubble diverter 2703 is abutting base 2704, yielding a minimal actuatable ionic current, as shown at 2722.

In FIG. 27B, as shown at 2750, adjustment mechanism 2719 has been actuated by controller 2718 to raise bubble diverter 2703. In this configuration, the bottom edge 2720 of bubble diverter 2703 no longer is in contact with base 2704. Rather, a gap 2752 of height h2 is generated around the perimeter of bubble diverter 2703. Ionic current though bubble diverter 2703 thus increases, as shown at 2755. In some examples, portions of bubble diverter 2703 insert into base 2704, such that the height h1 of apertures 2712 and 2714 can be adjusted. For example, a dynamic seal can be provided around holes in base 2704 so that portions of bubble diverter raises into and lowers out of base 2704.

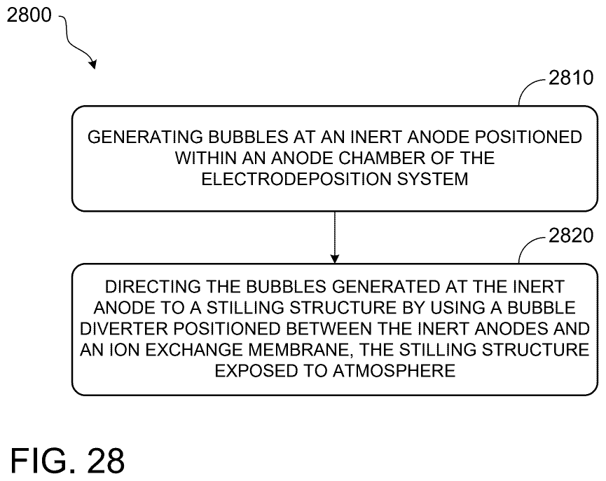

FIG. 28 shows a flow diagram illustrating an example method 2800 of operating an electrodeposition system, such as electroplating tool 2200, electrodeposition system 2300, and electrodeposition systems comprising anode chambers 2602 or 2702. At 2810, method 2800 comprises generating bubbles at an inert anode positioned within an anode chamber of the electrodeposition system by applying a voltage across the inert anode and a substrate. At 2820, method 2800 comprises directing the bubbles generated at the inert anode to a stilling structure by using a bubble diverter, the stilling structure being exposed to atmosphere. In some examples, directing bubbles to the stilling structure comprises biasing a flow of the bubbles to at least one channel leading to an anolyte circulation loop. In some examples, method 2800 further comprises flowing anolyte through the anolyte circulation loop such that the bubbles enter the stilling structure upstream of a circulation pump. In some examples, method 2800 further comprises flowing anolyte through a contactor located downstream of the stilling structure, the contactor configured to remove dissolved gases from the anolyte.

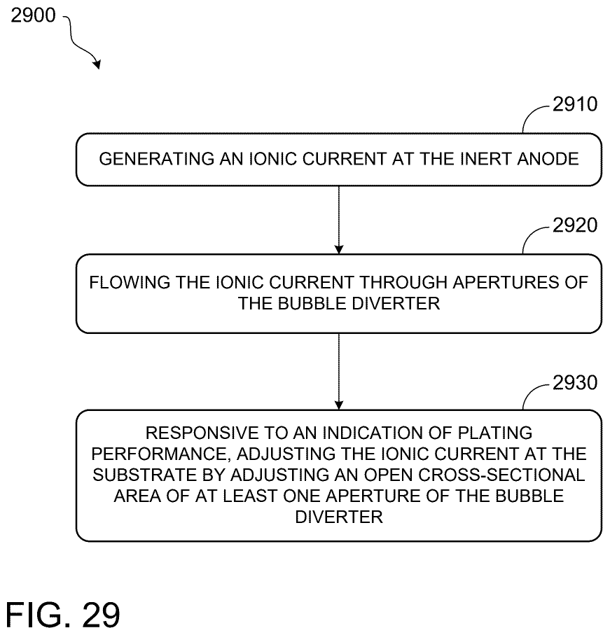

FIG. 29 shows a flow diagram illustrating an example method 2900 for adjusting ionic current in an electrodeposition system comprising an inert anode, such as electrodeposition systems comprising anode chambers 2602 or 2702. At 2910, method 2900 includes generating an ionic current at the inert anode. At 2920, method 2900 includes flowing the ionic current through apertures of the bubble diverter. At 2930, method 2900 includes, responsive to an indication of plating performance, adjusting the ionic current at a substrate by adjusting an open cross-sectional area of at least one aperture of the bubble diverter. In some examples, the open cross-sectional area of the apertures via a shutter system. In some examples, the open cross-sectional area of the apertures can be adjusted by adjusting a position of the bubble diverter relative to a base of the anode chamber. As an example, adjusting the ionic current comprises maintaining a voltage applied between the inert anode and a substrate. In some examples, adjusting the ionic current can be performed during an electrodeposition operation. Further, in some examples, adjusting the ionic current can be performed prior to an electrodeposition operation. In some examples, the indication of plating performance includes a sensed current at the substrate.

Such a method can help to carry away bubbles generated at the inert anode while the bubbles are in suspension. In such a manner, the gas bubbles may not settle on the ion exchange membrane and interfere with electrodeposition.

In some embodiments, the methods and processes described herein may be tied to a computing system of one or more computing devices. In particular, such methods and processes may be implemented as a computer-application program or service, an application-programming interface (API), a library, and/or other computer-program product.

FIG. 30 schematically shows a non-limiting example of a computing system 3000 that can enact one or more of the methods and processes described above. Computing system 3000 is shown in simplified form. Computing system 3000 may take the form of one or more personal computers, workstations, computers integrated with substrate processing tools, and/or network accessible server computers.

Computing system 3000 includes a logic subsystem 3002 and a storage subsystem 3004. Computing system 3000 may optionally include a display subsystem 3006, input subsystem 3008, communication subsystem 3010, and/or other components not shown in FIG. 30. Computing systems 150, 152, 1340, 2240, and 2245, and controllers 1608, 2014, 2620, and 2178, are examples of computing system 3000.

Logic subsystem 3002 includes one or more physical devices configured to execute instructions. For example, the logic subsystem may be configured to execute instructions that are part of one or more applications, services, programs, routines, libraries, objects, components, data structures, or other logical constructs. Such instructions may be implemented to perform a task, implement a data type, transform the state of one or more components, achieve a technical effect, or otherwise arrive at a desired result.

The logic subsystem may include one or more processors configured to execute software instructions. Additionally or alternatively, the logic subsystem may include one or more hardware or firmware logic subsystems configured to execute hardware or firmware instructions. Processors of the logic subsystem may be single-core or multi-core, and the instructions executed thereon may be configured for sequential, parallel, and/or distributed processing. Individual components of the logic subsystem optionally may be distributed among two or more separate devices, which may be remotely located and/or configured for coordinated processing. Aspects of the logic subsystem may be virtualized and executed by remotely accessible, networked computing devices configured in a cloud-computing configuration.

Storage subsystem 3004 includes one or more physical devices configured to hold instructions 3012 executable by the logic subsystem to implement the methods and processes described herein. When such methods and processes are implemented, the state of storage subsystem 3004 may be transformed—e.g., to hold different data.

Storage subsystem 3004 may include removable and/or built-in devices. Storage subsystem 3004 may include optical memory (e.g., CD, DVD, HD-DVD, Blu-Ray Disc, etc.), semiconductor memory (e.g., RAM, EPROM, EEPROM, etc.), and/or magnetic memory (e.g., hard-disk drive, floppy-disk drive, tape drive, MRAM, etc.), among others. Storage subsystem 3004 may include volatile, nonvolatile, dynamic, static, read/write, read-only, random-access, sequential-access, location-addressable, file-addressable, and/or content-addressable devices.

It will be appreciated that storage subsystem 3004 includes one or more physical devices. However, aspects of the instructions described herein alternatively may be propagated by a communication medium (e.g., an electromagnetic signal, an optical signal, etc.) that is not held by a physical device for a finite duration.

Aspects of logic subsystem 3002 and storage subsystem 3004 may be integrated together into one or more hardware-logic components. Such hardware-logic components may include field-programmable gate arrays (FPGAs), program- and application-specific integrated circuits (PASIC/ASICs), program- and application-specific standard products (PSSP/ASSPs), system-on-a-chip (SOC), and complex programmable logic devices (CPLDs), for example.

When included, display subsystem 3006 may be used to present a visual representation of data held by storage subsystem 3004. This visual representation may take the form of a graphical user interface (GUI). As the herein described methods and processes change the data held by the storage subsystem, and thus transform the state of the storage subsystem, the state of display subsystem 3006 may likewise be transformed to visually represent changes in the underlying data. Display subsystem 3006 may include one or more display devices utilizing virtually any type of technology. Such display devices may be combined with logic subsystem 3002 and/or storage subsystem 3004 in a shared enclosure, or such display devices may be peripheral display devices.

When included, input subsystem 3008 may comprise or interface with one or more user-input devices such as a keyboard, mouse, or touch screen. In some examples, the input subsystem may comprise or interface with selected natural user input (NUI) componentry. Such componentry may be integrated or peripheral, and the transduction and/or processing of input actions may be handled on- or off-board. Example NUI componentry may include a microphone for speech and/or voice recognition, and an infrared, color, stereoscopic, and/or depth camera for machine vision and/or gesture recognition.

When included, communication subsystem 3010 may be configured to communicatively couple computing system 3000 with one or more other computing devices. Communication subsystem 3010 may include wired and/or wireless communication devices compatible with one or more different communication protocols. As non-limiting examples, the communication subsystem may be configured for communication via a wireless telephone network, or a wired or wireless local-or wide-area network. In some examples, the communication subsystem may allow computing system 3000 to send and/or receive messages to and/or from other devices via a network such as the Internet.

It will be understood that the configurations and/or approaches described herein are exemplary in nature, and that these specific examples are not to be considered in a limiting sense, because numerous variations are possible. The specific routines or methods described herein may represent one or more of any number of processing strategies. As such, various acts illustrated and/or described may be performed in the sequence illustrated and/or described, in other sequences, in parallel, or omitted. Likewise, the order of the above-described processes may be changed.

The subject matter of the present disclosure includes all novel and non-obvious combinations and sub-combinations of the various processes, systems and configurations, and other features, functions, acts, and/or properties disclosed herein, as well as any and all equivalents thereof.

1. An electrodeposition system, comprising:
a substrate holder;
a cathode chamber configured to hold a catholyte;
an anode chamber comprising an inert anode, the anode chamber configured to hold an anolyte; and
an intermediate chamber positioned between the cathode chamber and the anode chamber, the intermediate chamber separated from the cathode chamber by an ion exchange membrane.

2. The electrodeposition system of claim 1, wherein the intermediate chamber is separated from the anode chamber by a proton-impeding structure.

3. The electrodeposition system of claim 2, wherein the proton-impeding structure comprises a metal redox barrier configured to
receive growth of a metal film on an anode side of the metal redox barrier by reduction of metal ions from anolyte contacting the anode side of the metal redox barrier, and
provide metal ions to a solution contacting a cathode side of the metal redox barrier by oxidation of the metal redox barrier.

4. The electrodeposition system of claim 3, further comprising a mechanical bias element to bias the metal redox barrier toward the intermediate chamber.

5. The electrodeposition system of claim 3, wherein the metal redox barrier is configured to be rotatable to allow the anode side and cathode side to alternate orientations toward the intermediate chamber.

6. The electrodeposition system of claim 2, wherein the proton-impeding structure comprises an anion exchange membrane.

7. The electrodeposition system of claim 6, wherein the ion exchange membrane that separates the intermediate chamber and the cathode chamber comprises a second anion exchange membrane.

8. The electrodeposition system of claim 6, wherein the ion exchange membrane that separates the intermediate chamber and the cathode chamber comprises a cation exchange membrane.

9. The electrodeposition system of claim 6, further comprising a redox shuttle circulation system configured to provide a redox shuttle species to the anode chamber.

10. The electrodeposition system of claim 9, wherein the redox shuttle circulation system comprises a redox shuttle species regeneration chamber.

11. The electrodeposition system of claim 1, wherein the ion exchange membrane is a first cation exchange membrane and wherein the intermediate chamber is separated from the anode chamber by a second cation exchange membrane.

12. The electrodeposition system of claim 11, further comprising:
a copper oxide module fluidly coupled to the intermediate chamber.

13. An electrodeposition system, comprising:
a cathode chamber configured to hold a catholyte;
a substrate holder configured to expose a substrate to the catholyte during an electrodeposition process; and
an inert anode assembly comprising
one or more inert anodes,
two or more anolyte flow channels that define segmented areas of anolyte flow across the one or more inert anodes, and
an ion exchange membrane positioned between the cathode chamber and the two or more anolyte flow channels.

14. The electrodeposition system of claim 13, wherein the inert anode assembly further comprises a cathode chamber bottom component comprising an opening that is positioned opposite an anolyte flow channel of the two or more anolyte flow channels.

15. The electrodeposition system of claim 14, wherein the two or more anolyte flow channels are formed in an anolyte channel component, and wherein the ion exchange membrane is positioned between the cathode chamber bottom component and the anolyte channel component.

16. The electrodeposition system of claim 15, wherein the inert anode assembly further comprises an intermediate channel component positioned between the cathode chamber bottom component and the anolyte channel component, wherein the ion exchange membrane is a first ion exchange membrane positioned between the intermediate channel component and the anolyte channel component, and further comprising a second ion exchange membrane positioned between the cathode chamber bottom component and the intermediate channel component.

17. An electrodeposition system, comprising:
a cathode chamber configured to hold a catholyte;
an anode chamber configured to hold an anolyte;
a membrane frame supporting an ion exchange membrane positioned between the cathode chamber and the anode chamber;
a substrate holder configured to expose a substrate to the catholyte during an electrodeposition process;
an inert anode positioned within the anode chamber; and
a bubble diverter positioned to direct a flow of bubbles generated at the inert anode to a stilling structure at which the bubbles are vented to atmosphere.

18. The electrodeposition system of claim 17, wherein the bubble diverter extends around a peripheral portion of the ion exchange membrane.

19. The electrodeposition system of claim 17, further comprising an anolyte circulation loop comprising a circulation pump, wherein the bubble diverter directs the flow of bubbles to the anolyte circulation loop, and wherein the stilling structure is positioned upstream of the circulation pump, the stilling structure being exposed to atmosphere.

20. The electrodeposition system of claim 19, wherein the anolyte circulation loop further comprises a contactor downstream of the stilling structure and upstream of the circulation pump, the contactor configured to remove dissolved gases from the anolyte.
